(19) United States
(12) Patent Application Publication
(10) Pub. No.: US 2010/0032008 A1
(43) Pub. Date: Feb. 11, 2010

(54) ZINC OXIDE MULTI-JUNCTION PHOTOVOLTAIC CELLS AND OPTOELECTRONIC DEVICES

(75) Inventor: Bunmi T. ADEKORE, Arlington, MA (US)

Correspondence Address: WILMERHALE/BOSTON, 60 STATE STREET, BOSTON, MA, 02109, US

(73) Assignee: LUMENZ LLC, Boston, MA (US)

(21) Appl. No.: 12/478,626

(22) Filed: Jun. 4, 2009

Related U.S. Application Data
(63) Continuation of application No. PCT/US07/25432, filed on Dec. 11, 2007.
(60) Provisional application No. 60/874,136, filed on Dec. 11, 2006.

(51) Int. Cl. H01L 31/00; H01B 1/02; B32B 17/06; B32B 9/04; C30B 25/02; H01L 31/02; H01L 29/861; H01L 29/26; H01S 5/00

(52) U.S. Cl. 136/255; 136/261; 252/519.51; 428/432; 428/446; 428/697; 117/88; 438/85; 257/43; 372/43.01; 257/E31.11; 257/E29.327; 257/E29.079

(57) ABSTRACT

Devices and methods of fabrication of ZnO based single and multi-junction photovoltaic cells are disclosed. ZnO based single and multijunction photovoltaic cells, and other optoelectronic devices include p-type, n-type, and undoped materials of ZnₓA₁₋ₓO_{y}B_{1-y}, wherein the alloy composition A and B, expressed by x and y, respectively, varies between 0 and 1. Alloy element A is selected from related elements including Mg, Be, Ca, Sr, Cd, and In and alloy element B is selected from a related elements including Te and Se. The selection of A, B, x and y, allows tuning of the material's band gap. The band gap of the material may be selected to range between approximately 1.4 eV and approximately 6.0 eV. ZnₓA₁₋ₓO_{y}B_{1-y} based tunnel diodes may be formed and employed in ZnₓA₁₋ₓO_{y}B_{1-y} based multi-junction photovoltaic devices. ZnₓA₁₋ₓO_{y}B_{1-y} based single and multi-junction photovoltaic devices may also include transparent, conductive heterostructures and highly doped contacts to ZnO based substrates.

### RELATED APPLICATIONS

This application claims the benefit of priority under 35 U. S.C. §120 of Patent Cooperation Treaty Application No. PCT/US07/25432, filed Dec. 11, 2007, designating the United States and entitled “Zinc Oxide Multi-Junction Photovoltaic Cells and Optoelectronic Devices,” which claims the benefit of priority under 35 USC §119(e) to U.S. Patent Application No. 60/874,136 entitled, “Fabrication of Zinc Oxide Multi-junction Photovoltaic Cells Using Iterative Nucleation and Growth”, filed Dec. 11, 2006, which is incorporated herein by reference in its entirety.

This application is related to U.S. patent application Ser. No. 11/551058 entitled “Shallow acceptor conductivity in ZnO crystals,” filed Oct. 19, 2006, which is incorporated herein by reference in its entirety.

### BACKGROUND

Photovoltaics is the direct conversion of light into electricity at the atomic level. Some materials exhibit a property known as the photoelectric effect that causes them to absorb photons of light and release electrons. When these free electrons are captured, an electric current results that can be used as electricity.

ZnO crystals have been found to be highly useful in applications which include: (1) optoelectronic devices employed for the emission and detection of electromagnetic waves, (2) high frequency and transparent transistors, (3) biological devices ranging from nano-units for drug delivery to gene tagging and identification devices. ZnO may also be used in applications concerning the synthesis of radiation hard devices including space and terrestrial photovoltaics. Silicon and germanium single junction photovoltaics have high photocurrent due to the proximity of the bandgaps of this material to the wavelength corresponding to the 50% of solar energy. However, these materials have relatively poor absorption coefficients and thus very thick layers of these materials are required. Moreover, the photovoltage of these materials are relatively small, leading to reduced power output, which is the product of the photocurrent and the photovoltage.

Materials which have larger bandgaps such as GaAs have increased photovoltages but reduced photocurrent since the cross-section of captured photons in these materials is reduced due to the misalignment of the bandgaps of these materials to wavelengths corresponding to 50% of solar energy. Multijunctions can take advantage of both small and large bandgap materials by increasing the cross-section of photons captured over the entire spectrum of solar radiation such that the wide bandgap materials can capture short wavelength photons and the smaller bandgap materials can capture longer wavelength photons. Losses in photocurrent are typically more than compensated for by enormous gains in photovoltage in multi-junction photovoltaics because of the higher bandgap energies. Technologies offering a robust materials for forming multi-junction photovoltaics would be desirable.

The performance of multi-junction photovoltaics is limited due to heteroepitaxy. For instance, present day multi-junction photovoltaic cells utilize three different material families, III-Phosphides, silicon, and germanium. The lattice constants of these materials are significantly different thus leading into high density of line defects such as dislocations as the epitaxy is directed from Ge to Si and then to III-Phosphides. Dislocations at the interfaces of materials stacked sequentially to capture photons ranging short to long wavelength photons act as a drain to these photons and more importantly, shorten the diffusion lengths and lifetimes of photo-generated minority carriers thus reducing the photocurrent. Furthermore, impurity segregation may occur at these dislocations and may introduce mid bandgap states within the energygap of the materials and thereby reduce the photovoltage generated by the device. In all, dislocations generated as a result of heteroepitaxial deposition of mismatched crystals decrease the overall power of photovoltaic single and multi-junction devices.

### SUMMARY

ZnO-based materials having energy band gaps in the red and/or near IR range of the energy spectrum, e.g., less than about 1.9 eV are provided. The ZnO-based materials can be formed as single crystal thin films.

ZnO single junction photovoltaic devices also are described, which incorporate the these novel ZnO-based materials.

Multiple junction photovoltaic cells using a combination of materials with varying bandgap energy to efficiently capture a larger range of photon energies are also provided. The multiple junction cells do not compromise the photovoltage or lead to heat dissipation as is the case in single junction cells. Multi-junction photovoltaics based on ZnO are achieved using thin film deposition techniques, the ionization of shallow acceptors and the synthesis of ZnO alloys with varying energy gaps.

In one aspect, crystalline ZnₓA₁₋ₓO_{y}B_{1-y} layers are provided, in which the energy gap is tuned between 6.0 eV and 1.4 eV. The composition of A and B, as expressed by x and y, respectively, may vary independently or dependently between 0 and 1 and A is selected from related elements including Mg, Be, Ca, Sr, Cd, and In, and B is selected from related elements including Te and Se. Other elements may also be used, in accordance with the desired application.

In one or more embodiments, thin film deposition and doping of ZnₓA₁₋ₓO_{y}B_{1-y} crystals is achieved using thin film deposition techniques such as molecular beam epitaxy, plasma CVD, metal organic CVD (MOCVD) and the like. Crystalline ZnO nanocolumns can be obtained by electrodeposition on polycrystalline conductive glass and on monocrystalline GaN substrates. The thin film of ZnₓA₁₋ₓO_{y}B_{1-y} crystals may be applied onto ZnO, III-nitride, sapphire, silicon, ScAlMg, or glass substrates.

In another aspect, thin films of ZnₓA₁₋ₓO_{y}B_{1-y} crystals may be employed in the fabrication of single junction ZnO-based photovoltaic devices. Single junction photovoltaic devices having thin films of ZnₓA₁₋ₓO_{y}B_{1-y} crystals may be fabricated such that photon energies between approximately 6.0 eV and 1.0 eV can be absorbed.

In another aspect, thin films of ZnₓA₁₋ₓO_{y}B_{1-y} crystals may be sequentially stacked to form multi-junction photovoltaic devices. Multi-junction devices having sequentially deposited layers of ZnₓA₁₋ₓO_{y}B_{1-y} may be fabricated such that phonon energies between approximately 6.0 eV and 1.4 eV may be absorbed.

In one or more embodiments, the films of ZnₓA₁₋ₓO_{y}B_{1-y} are sequentially deposited, from a material having the lower bandgap to a material having the higher bandgap. The stack of ZnₓA₁₋ₓO_{y}B_{1-y} films is arranged so that the topmost ZnₓA₁₋ₓO_{y}B_{1-y} film is the lower bandgap material. Deposition of layers sequentially from low to high energy, in either n- or p-type doped materials, compensates favorably for intrinsic diffusion lengths and lifetimes of minority carriers. Because n-type and p-type carriers have different diffusion lengths, layers may be stacked in a sequence that facilitates discharge of carriers to external circuitry.

In one or more embodiments, layers of ZnₓA₁₋ₓO_{y}B_{1-y} based crystals may be sequentially deposited, from a material having the higher bandgap to a material having the lower bandgap. The stack of ZnₓA₁₋ₓO_{y}B_{1-y} films is arranged such that the topmost ZnₓA₁₋ₓO_{y}B_{1-y} film is the higher bandgap material.

In one or more embodiments, a ZnₓA₁₋ₓO_{y}B_{1-y} based transitional epitaxial layer may be deposited. The transitional epitaxial layer may be used to assist lattice matching between the substrate and the first layer of the adjacent photovoltaic junction. Lattice matching may be achieved by way of compositional grading of the ZnₓA₁₋ₓO_{y}B_{1-y} alloy or the transition epitaxial layer may provide changes to composition as a step function. Transitional layers can be used between any layer of different composition, for example, between adjacent photovoltaic junctions, or between a layer of a photovoltaic junction and a tunneling diode or a connection to an external contact layer.

In another aspect, ZnₓA₁₋ₓO_{y}B_{1-y} based resonant tunneling diodes may be fabricated by degenerative doping. ZnₓA₁₋ₓO_{y}B_{1-y} resonant tunnel diodes, wherein A is selected from Mg, Be, Ba, Ca, Sr, Cd, In and B is selected from Te and Se, enable negative resistance and/or enhanced current transition through the use of bandgap offsets achieved by doping.

In another aspect, ZnₓA₁₋ₓO_{y}B_{1-y} based resonant tunneling diodes may fabricated to form bandgap offsets. ZnₓA₁₋ₓO_{y}B_{1-y} based resonant tunneling diodes may be used to align doped and/or undoped layers of ZnₓA₁₋ₓO_{y}B_{1-y} and to form hetero-junctions with sufficient bandgap offsets to enable current tunneling.

In still another aspect, layers of different bandgaps are interspaced by ZnₓA₁₋ₓO_{y}B_{1-y} based resonant tunneling diodes. In one or more embodiments, the ZnₓA₁₋ₓO_{y}B_{1-y} resonant tunneling diodes are interposed between doped and/or undoped layers of ZnₓA₁₋ₓO_{y}B_{1-y} to form multi-unction photovoltaic devices as described herein. In one or more embodiments, interspacing the layers of different bandgap materials with ZnₓA₁₋ₓO_{y}B_{1-y} based resonant tunneling diodes resolves lattice matching problems and facilitates current flow between the layers of different bandgap materials.

In one or more embodiments, the photovoltaic cell further includes doped or undoped ZnₓA₁₋ₓO_{y}B_{1-y} based heterostructures disposed on the topmost cell of multi-junction photovoltaic devices. This construction improves the efficiency of the ZnₓA₁₋ₓO_{y}B_{1-y} based photovoltaic devices.

In one or more embodiments, the photovoltaic cell further includes a heavily doped ZnₓA₁₋ₓO_{y}B_{1-y} based back layer interposed between the innermost cell and substrate and/or back surface contact. This construction improves the efficiency of the ZnₓA₁₋ₓO_{y}B_{1-y} based photovoltaic devices.

In one or more embodiments, the photovoltaic cell further includes a heavily doped region of the substrate in closest proximity to the back surface contact. This construction improves the efficiency of the ZnₓA₁₋ₓO_{y}B_{1-y} based photovoltaic devices.

In one or more embodiments, the photovoltaic cell further includes a transparent contact based on ZnA₁₋ₓO transparent alloy, where A can be selected from In, Ga, or Al on ZnₓA₁₋ₓO_{y}B_{1-y} devices. Fabricating the ZnO based transparent contact based on the ZnA₁₋ₓO transparent alloy includes the metallization of ZnO photovoltaic devices through self-contacting structures comprising of undoped, and/or lightly doped and/or heavily doped ZnₓA₁₋ₓO_{y}B_{1-y} alloys.

In one or more embodiments, a zinc oxide composition comprising ZnₓA₁₋ₓO_{y}B_{1-y} is provided, where x can vary from 0 to 1 and 0<y<1. A may be selected from related elements including Mg, Be, Ca, Sr, Cd, and In and B may be selected from a related elements including Te and Se.

In one or more embodiments, a semiconductor photovoltaic device having at least one junction is provided. The semiconductor photovoltaic device includes an n-type semiconductor material, and a p-type semiconductor material disposed in contact with the n-type semiconductor material. Each of the n-type and p-type semiconductor materials comprises a compound of the form ZnₓA₁₋ₓO_{y}B_{1-y}, (0<x≦1) (0<y<1), wherein A is selected from the group of related elements comprising Mg, Be, Ca, Sr, Ba, Mn, Cd, and In, wherein B is selected from the group of related elements comprising Te and Se. Each of x, y, A, and B is selected to provide a junction bandgap corresponding to selected spectral range for absorption by the photovoltaic device.

In one or more embodiments, a semiconductor photovoltaic device is provided. The semiconductor photovoltaic device includes a plurality of semiconductor junctions, each comprising an n-type semiconductor material and a p-type semiconductor material disposed in contact with the n-type semiconductor material. Each of the first doped semiconductor material and the second doped semiconductor material comprises a compound of the form ZnₓA₁₋ₓO_{y}B_{1-y}, (0≦x≦1) (0≦y≦1), and each of x, y, A, and B is selected to provide a bandgap for the semiconductor junction. The plurality of semiconductor junctions are selected to correspond to a selected spectral range for the semiconductor photovoltaic device.

In one or more embodiments, a method of making a photodiode is provided. The method of making a photodiode includes epitaxially growing a first p/n junction on a crystalline substrate in a CVD process in a continuous process. The first p/n junction comprises an n-type semiconductor material and a p-type semiconductor material. Each of the first doped semiconductor material and the second doped semiconductor material comprises a compound of the form ZnₓA₁₋ₓO_{y}B_{1-y} (0≦x≦1) (0≦y≦1), and wherein each of x, y, A, and B is selected to provide a bandgap for the semiconductor junction, by varying the composition of a vapor source of zinc, a vapor source of A, a vapor source of O and a vapor source of B.

In one or more embodiments, a device including at least one n-type semiconductor material and at least one p-type semiconductor material disposed in contact with the n-type semiconductor material is provided. Each of the n-type semiconductor material and the p-type semiconductor material comprises a compound of the form ZnₓA₁₋ₓO_{y}B_{1-y}, (0≦x≦1) (0≦y≦1), and each of x, y, A, and B is selected to provide a bandgap for the semiconductor junction.

In one or more embodiments, a device is selected from the group consisting of photodiodes, solar cells, optical detectors, optical emitters, LEDs, and laser diodes.

In one or more embodiments, an optoelectronic device, includes at least one n-doped semiconductor material, at least one p-doped semiconductor material, and at least one semiconductor material disposed in contact with each of the n-doped semiconductor material and the p-doped semiconductor material. Each of the n-doped semiconductor material, the p-doped semiconductor material, and the semiconductor material comprises a compound of the form ZnₓA₁₋ₓO_{y}B_{1-y}, (0≦x≦1) (0≦y≦1), wherein each of A, B, x and y is selected to provide a bandgap for the semiconductor material.

In one or more embodiments, an optoelectronic device such as a LED emits light at a wavelength of greater than approximately 650 nm.

In one or more embodiments, an optoelectronic device comprises a vertical-cavity surface-emitting laser (VCSEL).

In one or more embodiments, an optoelectronic device comprises a plurality of optical emitters. Each optical emitter includes at least one n-doped semiconductor material, at least one p-doped semiconductor material, and at least one semiconductor material disposed in contact with each of the n-doped semiconductor material and the p-doped semiconductor material. Each of the n-doped semiconductor material, the n-doped semiconductor material, and the semiconductor material comprises a compound of the form ZnₓA₁₋ₓO_{y}B_{1-y}, (0≦x≦1) (0≦y≦1), wherein each of A, B, x and y is selected to provide a bandgap for the semiconductor material. The bandgap for the semiconductor material of each optical emitter is selected to emit electromagnetic radiation at a discrete portion of the energy spectrum.

In one or more embodiments, an optoelectronic device includes a waveguide for guiding electromagnetic radiation emitted by each of a plurality of optical emitters so that the optoelectronic device emits white RGB electromagnetic radiation.

In one or more embodiments, an optoelectronic device is configured and arranged to emit light at one or more wavelengths, comprising a ZnO-based material of the composition ZnₓA₁₋ₓB_{1-y}O_{y} where x can vary from 0 to 1 and 0≦y≦1, A is selected from related elements including Mg, Be, Ca, Sr, Cd, and In and B is selected from a related elements including Te and Se.

In one or more embodiments, a light emitting diode (LED) comprises a ZnO-based material of the composition ZnₓA₁₋ₓB_{1-y}O_{y}, where x can vary from 0 to 1 and 0≦y≦1, A is selected from related elements including Mg, Be, Ca, Sr, Cd, and In and B is selected from a related elements including Te and Se.

In one or more embodiments, a photodiode comprises a ZnO-based material of the composition ZnₓA₁₋ₓB_{1-y}O_{y}, where x can vary from 0 to 1 and 0≦y≦1, A is selected from related elements including Mg, Be, Ca, Sr, Cd, and In and B is selected from a related elements including Te and Se.

In one or more embodiments, an optical detector comprises a ZnO-based material of the composition ZnₓA₁₋ₓB_{1-y}O_{y}, where x can vary from 0 to 1 and 0≦y≦1, A is selected from related elements including Mg, Be, Ca, Sr, Cd, and In and B is selected from a related elements including Te and Se.

In one or more embodiments, a laser diode comprises a ZnO-based material of the composition ZnₓA₁₋ₓB_{1-y}O_{y}, where x can vary from 0 to 1 and 0≦y≦1, A is selected from related elements including Mg, Be, Ca, Sr, Cd, and In and B is selected from a related elements including Te and Se.

### BRIEF DESCRIPTION OF THE DRAWINGS

The invention is described with reference to the following drawings which are provided for the purpose of illustration only and are not intended to be limiting of the invention. In the drawings:

FIG. 1A is an illustration of a single junction ZnₓA₁₋ₓO_{y}B_{1-y} photovoltaic device according to one or more embodiments.

FIG. 1B is a schematic illustration of a single junction ZnₓA₁₋ₓO_{y}B_{1-y} photovoltaic device disposed on a n-type substrate and including a transition layer according to one or more embodiments.

FIG. 1C is a schematic illustration of a single junction ZnₓA₁₋ₓO_{y}B_{1-y} photovoltaic device disposed on a p-type substrate and including a transition layer according to one or more embodiments.

FIG. 2 is an illustration of various examples of multi-junction ZnₓA₁₋ₓO_{y}B_{1-y} structures.

FIG. 3 is an example illustration of ZnxA1-xOyB1-y resonant tunnel diode structure;

FIG. 4 is an example illustration of ZnxA1-xOyB1-y based resonant tunneling interband diode structure which is undoped or doped;

FIG. 5 is an example illustration of multi-junction ZnxA1-xOyB1-y photovoltaic device interspaced with by ZnxA1-xOyB1-y based tunnel diode; and

FIG. 6 illustrates a plot of the electromagnetic spectrum of visible and ultraviolet light and indicates the typical amount of energy available from sunlight at a given eV.

FIG. 7 illustrates an example of an experimental determination of bowing parameters.

FIG. 8 illustrates an example of expected energy gap and lattice parameters of ZnCdOSe and ZnCdOTe compounds.

FIG. 9 is an example illustration of a structure of a ZnO-based Red Emitter.

FIGS. 10A, 10B, and 10C are example illustrations of three structures having ZnO based vertical cavity surface emitting lasers.

FIG. 11 is an example illustration of a monolithic device producing white RGB emission through the waveguided mixing.

### DETAILED DESCRIPTION

A typical photovoltaic cell includes a photoactive material disposed between two electrodes. Many photovoltaic (PV) devices use a single junction, or interface, to create an electric field within a semiconductor such as a PV cell.

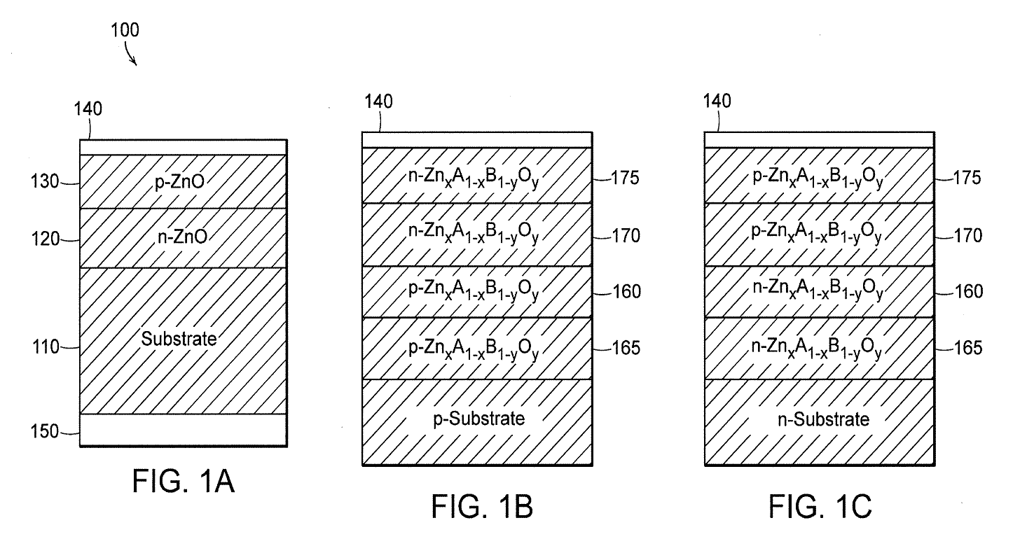

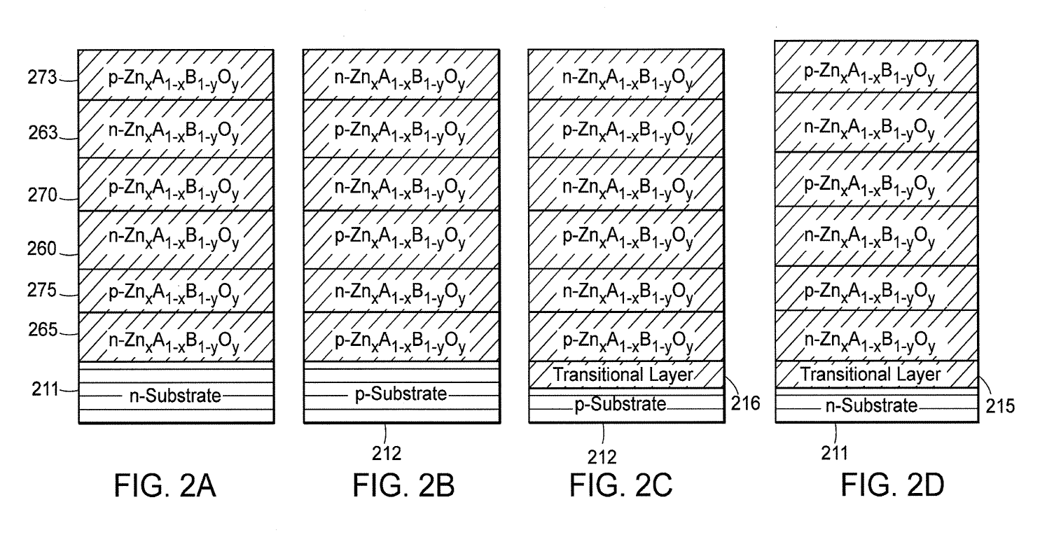

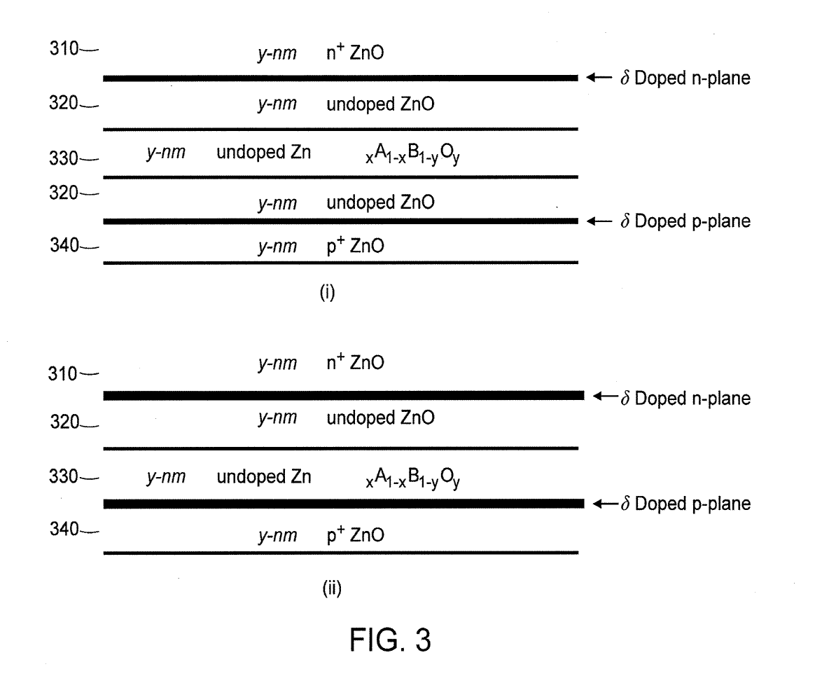

FIG. 1A is a schematically explanatory drawing of a photovoltaic element. In FIG. 1, a photovoltaic element 100 comprises a substrate 110, an n-type ZnO thin film layer 120, a p-type ZnO thin film layer 130, an upper transparent electrode 140 (which can be ZnO-based) and a lower electrical contact 150. The order of the n- and p-type layers is not fixed but may be selected according to the particular application. The photovoltaic element of FIG. 1 is normally irradiated with light from the side of the device including the transparent electrode 140, but it may be irradiated from the back side of the substrate 110. In that case, the substrate 110 is made of a light-transmitting material.

In a single-junction PV cell, only photons whose energy is equal to or greater than the band gap of the cell material can free an electron for an electric circuit. In other words, the photovoltaic response of single-junction cells is limited to the portion of the sun's spectrum whose energy is above the band gap of the absorbing material, and lower-energy photons are not used. One way to get around this limitation is to use two (or more) different cells, with more than one band gap and more than one junction, to generate a voltage. These are referred to as “multijunction” cells. Multijunction devices can achieve a higher total conversion energy because they can convert more of the energy spectrum of light to electricity.

ZnO is a promising and robust material for multi-junction photovoltaic cells. In one or more embodiments, a single junction or multijunction photovoltaic device is provided, which takes advantage of ZnO alloying at the Zn and O sites to provide a material having band gap energies over an energy spectrum ranging from about 1.0 eV to about 6.0 eV. ZnO-based materials are provided that have band gap energies as low as 1.0 eV, which permits energy absorption in the red and near IR regions of the energy spectrum.

Multiple junction photovoltaic cells use a combination of materials with varying bandgap energy to efficiently capture a larger range of photon energies in a manner which does not compromise the photovoltage or lead to heat dissipation as the case is in single junction cells. Multi-junction photovoltaics based on ZnO alloys can be achieved through the utility of reliable thin film deposition techniques, the ionization of shallow acceptors and the synthesis of ZnO alloys with varying energy gaps.

In one or more embodiments, deposition and bipolar doping of single crystalline films of ZnO and related alloys having bandgaps energies ranging from ultraviolet to red are described.

In one or more embodiments, the epitaxial stacking of ZnO with its alloy having altered lattice coefficient and bandgaps can be achieved with minimal defectivity, thus enabling intrinsic values minority carrier diffusion lengths and lifetimes. Transparent carrier blocking layers of type ZnₓA₁₋ₓO_{y}B_{1-y} can be employed in heterostructural manner to minimize surface recombination. Minimal thickness of ZnO can be utilized because of enhanced absorption coefficients, thereby reducing device size and increasing device efficiency. In certain embodiments, each active layer comprising an ZnO alloy will have a thickness of less than 5 μm (e.g. the pair of n-type and a p-type layers). In other embodiments, lower saturation currents of a higher bandgap materials are demonstrated.

In one or more embodiments, transparent self-contacts of ZnO are provided through doping of ZnO, eliminating the losses in efficiency due to non-transparent metallization.

In one or more embodiments, higher voltages corresponding to higher energies of the electromagnetic spectrum can be captured leading to higher photo-voltages within the PV device thereby compensating for losses in photocurrents and thus resistive losses due to I²R in the external circuit.

The band gaps characterizing a zinc-oxide based materials may be carefully engineered through the use of alloying techniques. The type and proportion of alloying element used with ZnO to form zinc oxide-based compounds, ZnₓA_{y}O, may be varied to tune the characteristic band gap towards a selected region of the energy spectrum. For example, if alloy element A is selected to be one of Mg or Cd, the band gap of the material may be tuned to the red or the blue regions of the energy spectrum, respectively, and may be suitable for applications in these spectral ranges. Other alloying elements such as Be, Ca, Sr, In, and B, can be alloyed with ZnO to achieve similar results. Alloying ZnO with Be, Ca and Sr tunes the bandgap to the blue region of the energy spectrum while alloying ZnO with In and B tunes the bandgap to the red region of the energy spectrum. Typical ranges for x are 0.01 to about 0.3, and x can range up to the solubility limit of the alloying element. The level of alloying element is selected to obtained the desired red or blue shift in the band gap energy.

A technological limitation of ZnO, thus far, is the lack of viable ZnO alloys with bandgaps tuned to the red region of the energy spectrum. In one or more embodiments, a ZnO alloy is described having a band gap in the red or near of region of the energy spectrum. The zinc-oxide compound has the composition ZnₓA₁₋ₓO_{y}B_{1-y} in which A is selected from Mg, Cd, Be, Ca, Sr, In and B, and B is selected from Se or Te, 0≦x≦1 and 0≦y≦1. A zinc-oxide compound of the composition ZnₓA₁₋ₓO_{y}B_{1-y}, may be alloyed at two sites: the zinc site with alloying element A and the oxygen site with alloying element B. Appropriate selection of alloying elements for A and B, permit the band gap of the material to be tuned to between ultraviolet and the near IR. Tuning of the band gap of the material is performed by altering the concentration of the alloying elements A and B by selecting values of x and y, respectively. Typical alloying ranges for x and y are up to 40% A alloy, and up to 30% B alloy.

Alloying at either one of the zinc or the oxygen sites independently from one another, respectively with alloying materials A and B achieves a reduction in the material's band gap in such a way to permit absorption in the red range of the energy spectrum. Element B may be alloyed up to the solubility limits of the alloying element, typically up to about 30%. While there are typically no solubility limits to A alloying, there may be an upper limit to element concentrations, beyond which increased concentration has virtually no impact on the band gap of the material. Appropriate reduction of the band gap can be determined theoretically, or by empirical observation, e.g. making and measuring the band gap of ZnₓA₁₋ₓO_{y}B_{1-y}. Empirical observation may incorporate any variety of appropriate techniques including, for example, edge absorption measurement.

By way of example, alloying at the zinc site reduces the bandgap (eV) of the ZnO-based semiconductor; independently alloying with Te or Se at the oxygen site has a similar yet independent effect. When A is selected to comprise Cd to form an alloy, ZnₓCd₁₋ₓO_{y}, band gap alterations occur for 0.6<x<1; correspondingly, for concentrations of Cd up to 40%. When the concentration of Cd alloying at the zinc site exceeds 40%, no further effect on the band gap of the material is observed. The introduction of a second alloying element, B, at the oxygen site permits further tuning of the band gap, beyond the limits of band tuning provided by alloying element A. The concentration of alloying element A may be lowered (e.g. Cd concentration of 30%) and Te or Se may be alloyed at the oxygen site (e.g. Se concentration of approximately 3-5%). Te or Se alloy concentrations in the material may theoretically be increased to up to 30% by (i.e., y=0.7), however persons skilled in the art will also recognize practical limits. For example, the alloying concentration at the zinc and the oxygen sites will also be limited by structural factors like the atomic size of alloying elements or the limits beyond which crystal integrity will be compromised. Both A and B alloying elements jointly contribute toward lowering the band gap of the ZnₓA₁₋ₓO_{y}B_{1-y} material. However, empirical observation indicates that, in fact, by alloying at both the zinc and oxygen sites in the manner disclosed, the aforementioned limits on band gap reduction may be overcome. That is, a zinc oxide material jointly alloyed with A and B alloying elements, as described enables absorption in the red and IR range—otherwise unattainable with either alloying element independently used. In one or more embodiments, alloying elements for A and B are selected to the enable red absorption for energies below 1.9 eV. In some embodiments, alloying of up to 30 at % Se or Te (y=0.3), e.g., up to the solubility limit of the alloying element, is used to tune the band gap of the ZnO alloy to as low a 1.0 eV.

While not wishing to be bound by theory, applicants believe expanded the spectral absorption range of ZnₓA₁₋ₓO_{y}B_{1-y} materials is explained by a “Band Bowing” effect. By varying the concentration of each of the A and B alloying elements and observing the edge absorption characteristics of the material, a corresponding minimum band gap level may be empirically identified.

The phenomena of band bowing has been predicted to occur in hexagonal wurtzite materials such as group III-Nitrides and Zinc Oxide. The band bowing effect allows for a parabolic recess in the energy gap of compounds resulting from the solid solution of two semiconductors with dissimilar energy gaps. The predictions of the energy gap of the resulting compound as dictated by Vergard's rules, indicates a compositional dependent variation in the energy gap with a bowing factor which may induce a parabolic minima. Identification of the parabolic minima facilitates the realization of an alloy with energy gap lower than expected or even lower than the constituent parent binary compounds. By way of example, it is expected that the energy gap of an alloyed compound, INAlN, follows a physical relationship given below:

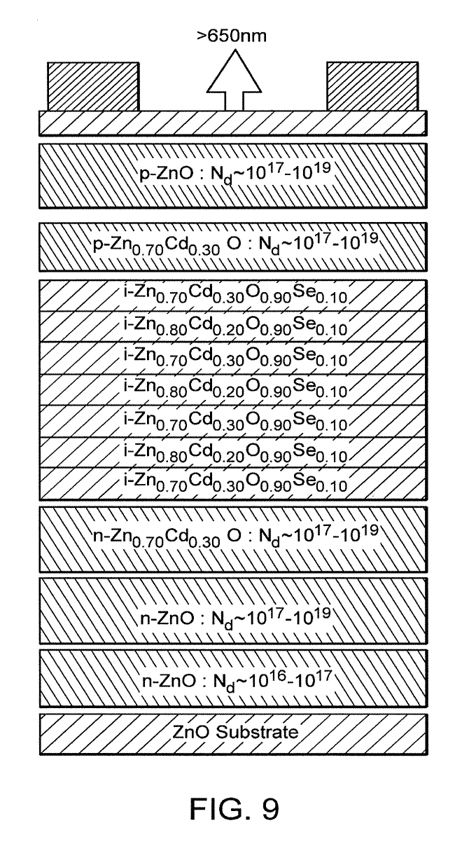

E_{g}^{In}^{₁₋ₓ}^{Al}^{ₓ}^{N}=x•Eg^{AlN}+Eg^{InN}•(1−x)−b•x•(1−x)

where x gives the compositional relationship and b is the bowing parameter. Bowing parameters as high as 3.8 eV and between 3.0 eV and 3.668 eV have been derived for InGaN and AlInN alloys respectively. FIG. 7 illustrates an experimental determination of bowing parameters in Group III-Nitride Alloys, InGaN and AlInN . Bowing parameters for the InGaN and AlInN alloys are published in the following references: M. D. McCluskey, C. G. Van de Walle, C. P. Master, L. T. Romano, and N. M Johnson, Appl. Phys. Lett. 72 2725 (1998); B. -T. Liou, S. -H Yen, and Y. -K. Kuo, Appl. Phys. A: Materials Science and Processing, 81 651 (2005); J. Wu, W. Walukewicz, K. M Yu, J. W. Ager III, S. X. Li, E. E. Haller, H. Lu, W. J. Schaff, “Universal Bandgap Bowing in Group III Nitride Alloys” Paper LBNL 51260, http://repositories.edlib.org/lbnl/LBNL-51260; and K. S. Kim, A. Saxler, P. Kung, M. Razeghi and K. Y. Lim, Appl. Phys. Lett. 71, 800 (1997), the entire contents of which are herein incorporated by reference.

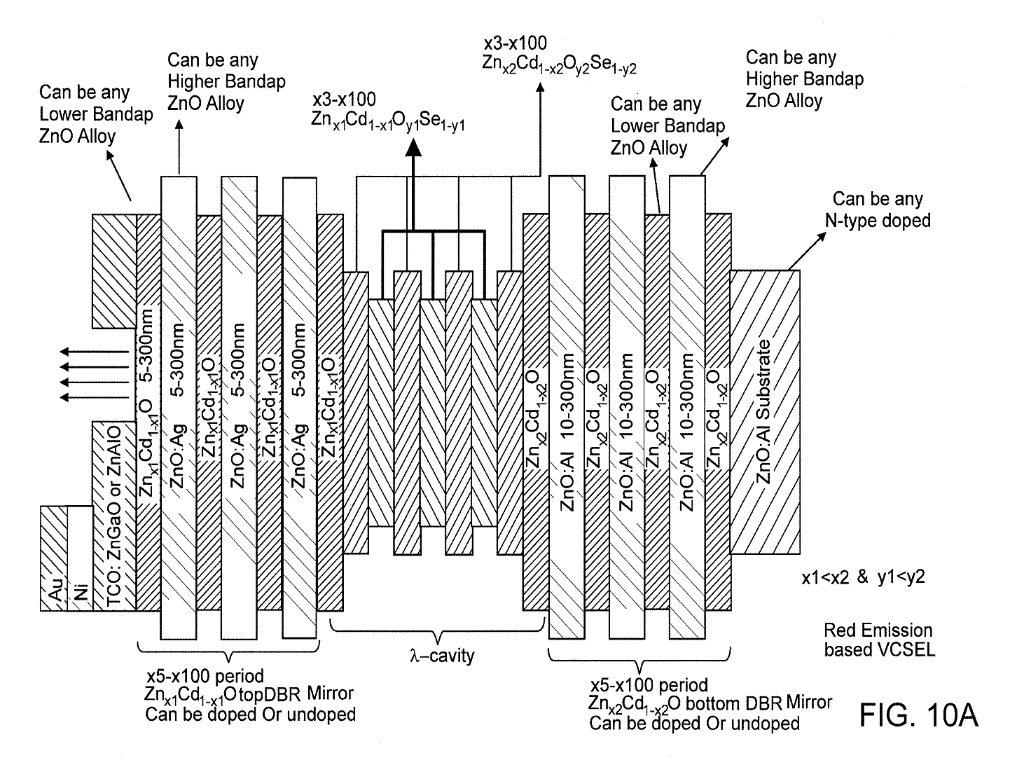

Without wishing to be bound by theory, applicants presently believe similar band bowing phenomena experimentally observed in regard to the aforementioned alloys may also be realized in Zinc Oxide based compounds. A solid solution of ZnO based alloys with dissimilar energy gaps yields a compound which has an energy gap that is lower than anticipated. The case of the solid solution of ZnCdO and CdSe provides one illustrative example. The extent of the lattice replacement of the Se on the Oxygen sublattice, and thus the miscibility of CdSe in ZnCdO, is classically dictated by Pauling rules wherein a geometric mismatch in ionic radii of less than 30% as well as isoelectronic compatibility is considered favorable. Whereas Se and Te have isoelectronic compatibility with the oxygen anionic sites, geometric mismatch is approximately 29% and 36% for these alloying elements, respectively. Deviations from Paulings classical rules, is expected in the case of the solid solution of CdTe and ZnCdO, where chemical interaction occurring between cation and anion sites of Cd and Te is expected to supercede and offset elastic (geometric) interactions. These elastic (geometric) interactions result from the Cd and Te ionic radii mismatch and thereby yield a special but favorable case of ZnCdOTe quaternary alloy. The bandgaps of ZnCdOSe and ZnCdOTe are expected to have significant bowing parameters allowing ZnO alloys with energy gaps reaching into the red. FIG. 8 illustrates theoretical energy gap and lattice parameters of ZnCdOSe, and ZnCdOTe compounds, predicted in accordance with band bowing data observed for AlInN alloys.

In one or more embodiments, ZnₓA₁₋ₓO_{y}B_{1-y} is formed as a crystalline thin film. Epitaxial layers of ZnO may be deposited onto ZnO, III-nitride, sapphire, silicon, ScAlMg, or glass substrates. The film may be deposited using conventional techniques such as molecular beam epitaxy, plasma CVD, metal organic CVD (MOCVD) and the like. Crystalline ZnO nanocolumns can be obtained by electrodeposition on polycrystalline conductive glass and on monocrystalline GaN substrates.

The implementation of zinc oxide materials in devices using p-n junctions hinges on the successful fabrication of n-type, and especially p-type, zinc oxide materials. One limitation of conventional thin film deposition techniques is the lack of reliable shallow acceptor ionization of the ZnO in the deposited film, which is desirable for the photovoltaic effect. Nitrogen acceptors on the oxygen sublattice by gas phase incorporation of nitrogen in ZnO has provided acceptor ionization; however, the degree of acceptor ionization is disappointingly low (1-3%). The poor degree of acceptor ionization of nitrogen atoms on the oxygen lattice, as well as limited solubility of nitrogen atoms in ZnO results in devices with commensurately poor optical efficiencies. There is currently no effective way to dope ZnO to form p-type ZnO.

U.S. patent application Ser. No. 11/551058, entitled “Zinc Oxide Based II-VI Compound Semiconductor Layers with Shallow Acceptor Conductivities and Methods of Forming Same,” which is hereby incorporated in its entirety by reference, discloses chemical vapor deposition fabrication techniques that enable the use of zinc oxide compounds in various applications. The fabrication techniques overcome difficulties relating to reliably fabricating p-type zinc oxide materials with sufficiently high concentrations of relatively shallow acceptor impurities operating as p-type dopants. The same methods used for p-type doping may also be used to prepare n-type zinc oxide by selection of the appropriate n-type dopants. An n-type zinc oxide may be prepared by using dopants including Al, Ga and In, or other appropriate elements. By way of example, ZnO may be doped with In at concentrations ranging from approximately 1×10² to 1×10²⁰ cm⁻³. The same fabrication techniques may be use to prepare n-type and p-type zinc oxide alloys of ZnₓA₁₋ₓO_{y}B_{1-y} composition, with A selected from a first group of elements, B selected from a second group of elements and the composition of A and B, as expressed by x and y, respectively, varying between 0 and 1. For example, by introducing In to ZnO at concentrations exceeding approximately 1×10²² cm⁻³, using the same techniques as those used to prepare the doped ZnO, one may create an alloy and tune the bandgap of the material to the red portion of the spectrum. The details of p-type zinc oxide alloys of ZnₓA₁₋ₓO_{y}B_{1-y} composition are provided below.

The epitaxial layers of ZnO or ZnO alloys may be doped with p-type species such as Ag, Au and K and which may have as much as 50% acceptor activation in ZnO. In a similar manner, epitaxial layers of ZnO or ZnO alloys may be doped with n-type species such as aluminum, gallium or indium.

The processing techniques for incorporating p-type dopants may include implanting the silver, potassium and/or gold dopants into the ZnO-based II-VI compound semiconductor layer at dose levels of greater than about 1×10¹³ cm⁻² and, for example, in a range from about ×10¹³ cm⁻² to about 1×10¹⁵ cm⁻². This implanting step may be performed as a single implanting step or as multiple implanting steps, which are performed at multiple different implant energy levels to thereby yield multiple implant peaks within the layer. An annealing step is then performed to more evenly distribute and activate the dopants and repair crystal damage within the layer. This annealing step may include annealing the ZnO-based II-VI compound semiconductor layer at a temperature in a range from about 250° C. to about 2000° C., in an ambient (e.g., chemically inert ambient) having a pressure in a range from about 25 mbar to about 7 kbar. In certain applications, it may be preferable to perform the annealing step at a temperature in a range from about 700° C. to about 700° C., in an oxygen ambient environment having a pressure of about 1 atmosphere. Similar ion implantation and anneal processes can be used for n-type dopants.

In yet other applications, a ZnO-based II-VI compound semiconductor layer may be formed using an atomic layer deposition (ALD) technique, e.g. a deposition technique includes exposing a substrate to a combination of gases. This combination may include a first reaction gas containing zinc at a concentration that is repeatedly transitioned (e.g. pulsed) between at least two concentration levels during a processing time interval, and a second reaction gas containing oxygen and a p-type dopant gas containing at least one p-type dopant species selected from a group consisting of silver, potassium, gold, or an n-type dopant gas, as appropriate. A concentration of oxygen in the second reaction gas may be repeatedly transitioned between at least two concentration levels. In particular a concentration of zinc in the first reaction gas and a concentration of oxygen in the second reaction gas may be transitioned in an alternating sequence so that relatively high zinc concentrations in the first reaction gas overlap with relatively low oxygen concentrations in the second reaction gas and vice versa.

Methods of forming a ZnO-based II-VI compound semiconductor layer may also include using an iterative nucleation and growth technique. This technique may include using an alternating sequence of deposition/growth steps that favor c-plane growth (i.e., vertical growth direction, which causes nucleation) at relatively low temperatures interleaved with a-plane growth (i.e., horizontal growth direction, which causes densification) at relatively high temperatures to coalesce the layer. In particular, iterative nucleation and growth may include depositing a plurality of first ZnO-based II-VI compound semiconductor layers at a first temperature in a range from about 200° C. to about 600° C. and depositing a plurality of second ZnO-based II-VI compound semiconductor layers at a second higher temperature in a range from about 400° C. to about 900° C. These first and second ZnO-based II-VI compound semiconductor layers are deposited in an alternating sequence so that a composite layer is formed.

Still other methods of forming a p-type ZnO-based II-VI compound semiconductor layer include exposing the substrate to a combination of a first reaction gas containing zinc, a second reaction gas containing oxygen and a p-type dopant gas containing at least one p-type dopant species selected from a group consisting of silver, potassium and gold, while simultaneously transitioning a temperature of the substrate between at least two temperatures. These two temperatures may include a first lower temperature in a range from about 200° C. to about 600° C. and a second higher temperature in a range from about 400° C. to about 900° C.

According to aspects of these embodiments, the concentration of the p-type dopant species in the p-type dopant gas is repeatedly transitioned between two concentration levels while the temperature of the substrate is also being transitioned between the two temperatures. In particular, the concentration of the p-type dopant species in the p-type dopant gas is transitioned in an alternating sequence relative to the transitioning of the temperature of the substrate so that relatively high concentrations of the p-type dopant species in the p-type dopant gas overlap with relatively low temperatures of the substrate and vice versa. Alternatively, the concentration of the p-type dopant species in the p-type dopant gas is transitioned so that relatively high temperatures of the substrate overlap with a timing of relatively high concentrations of the p-type dopant species in the p-type dopant gas.

Methods of forming an n-type ZnO-based II-VI compound semiconductor region may also include incorporating sufficient quantities of n-type dopants into a zinc sublattice within the ZnO based II-VI compound semiconductor region under processing conditions that yield a suitable n-type dopant concentration. In particular, a ZnO-based II-VI compound semiconductor layer may be formed on a substrate that is held at a temperature of greater than about 300° C., using a molecular beam epitaxy technique. This substrate may be selected from a group consisting of zinc oxide, III-nitrides, silicon, sapphire and/or glass, however, other substrates may also be used. In some such instances, the molecular beam epitaxy technique may include Knudsen evaporation of a zinc source. Alternatively, the steps of forming a ZnO-based II-VI compound semiconductor layer may include using a chemical vapor transport technique. In this technique, hydride or halide transport of zinc to a substrate may be provided. Still further embodiments may include using a physical vapor transport technique that includes transport of zinc to a substrate by evaporation, magnetron sputtering, flame hydrolysis deposition or sublimation. Liquid phase epitaxy techniques and solvus-thermal incorporation techniques may also be used to form the ZnO-based II-VI compound semiconductor region.

The above-mentioned fabrication techniques may be employed to produce structures and devices that employ n-type and p-type zinc oxide alloys of ZnₓA₁₋ₓO_{y}B_{1-y} composition. These techniques use processing conditions that yield a net n-type or p-type dopant concentration of greater than about 1×10¹⁷ cm⁻³ therein, for dopants having an acceptor ionization energy below about 355 meV. The processing conditions may also yield a dopant activation level of greater than about 10% for the dopants having the desired acceptor ionization energy. The n-type or p-type ZnO-based II-VI compound semiconductor layer may be a layer selected from a group consisting of ZnO, ZnMgO, ZnCaO, ZnBeO, ZnSrO, ZnBaO, ZnCdO, and ZnlnO and MgCdZnO layers and composites of these layers. Each of the above layers may be optionally further alloyed with alloying element B (B=Te, Se) to provide materials have band gap energies as low a 1.0 eV.

One advantage of the ALD technique, described above, is that it permits the deposition of both p- and n-layers using a single deposition system. The use of a single deposition technique and system, throughout the doping process, permits continuous and uninterrupted fabrication of the multiple layers in a single reaction chamber.

Methods and devices according to one or more embodiments of the invention are described.

### Single Junction ZnO Photovoltaics:

Single junction photovoltaic designed for optimal photocurrent can be achieved by bandgap engineering of ZnO to between approximately 6.0 eV and 1.0 eV, or 2.8 eV and 1.5 eV, or less than about 1.9 eV. Desired bandgaps may be achieved through the use of ZnO alloys such as ternary ZnₓCd₁₋ₓO which are created through organometallic vapour phase epitaxy processes (OMVPE) employing iterative nucleation and growth between 200° C. and 900° C. and pressures between 26 Torr and 100 Torr. Single junction photovoltaic devices are achieved by the combination of n-type dopants such as aluminum, gallium, and indium with p-type dopants such as gold, silver or potassium.

An exemplary single junction photovoltaic device is shown in FIG. 1A, where the p-ZnO and n-ZnO layers are one of the A- and/or B-alloyed ZnO compositions described herein. In one embodiment, single junction photovoltaic devices may have a measurable photo-response between 6.0 eV and 1.0 eV, e.g., between 2.8 and 1.90 eV using p-type and n-type doped ZnₓCd₁₋ₓO. In one embodiment, single junction photovoltaic devices may have a measurable photo-response between 2.0 and 1.6 eV; using p-type and n-type doped ZnₓCd₁₋ₓO_{y}Se_{1-y}. In one or more embodiments, the layers are deposited on a ZnO substrate or on a graded transitional layer from ZnO to the base ZnₓCd₁₋ₓO or ZnₓCd₁₋ₓO_{y}Se_{1-y} alloy such that x and y is equal to 1 at the substrate and compositional varied to the value of the base layer in the innermost cell. Such a transitional layer may also be prepared using the vapor deposition techniques described herein for the manufacture of active layers.

In other embodiments, the simple homojunction may be fabricated to have a p-type and n-type doped ZnCd₁₋ₓO with efficient spectral response between 2.8 and 1.90 eV or ZnCd₁₋ₓO_{y}Te_{1-y} with efficient spectral response between 2.0 and 1.5 eV. Preferably, the materials may be deposited on a ZnO substrate or on a graded transitional layer from ZnO to the base ZnCd₁₋ₓO alloy. Methods for forming the basic single junction photovoltaic device are described below.

Single junction photovoltaic devices may have an improved photo-response wherein simple homojunction is interspaced with an intrinsic, i-, or highly resistive layer of charge concentration lower than p- and n-adjoining regions to form a p-i-n junction.

In other embodiments, the substrate is crystalline ZnO, and the device further includes a transition layer interposed between the substrate and the active layers (e.g., p-type and n-type ZnO pair) having a composition and lattice structure that is intermediate between the two elements. Exemplary single junction photovoltaic devices are shown in FIGS. 1B and 1C, where the p-ZnO and n-ZnO layers (160, 170) are one of the A- and/or B-alloyed ZnO compositions described herein. The device further includes heterostructures (165, 175) consisting of, e.g., a ZnₓMg₁₋ₓO or a ZnₓCd₁₋ₓO in the ideal case or a ZnₓA₁₋ₓO wherein A is selected from a group consisting of Ca, Sr, Be, or Ba; doped of same polarity as the most exterior semiconducting layer. The compositions of the heterostructures are intermediate to that of the ZnO substrate and the alloyed active layer. This reduces the lattice strain in the epitaxy layers and the electric field due to the heterostructure reduces surface recombination of photo-generated charges at the surface. The heterostructure may have a single composition, or it may be made up of a graded composition, ranging from substantially ZnO at the interface with the substrate to substantially that of the active layer at the interface with the active layer (160/165). In one or more embodiments, the doped heterostructure functions as a low series resistance pass or intermediary to the final contact at the interface with the upper transparent contact layer (140/175).

In one aspect, single junction photovoltaic devices may have an improved photo-response, in which the simple homojunction possesses a barrier contact consisting of a metal such as Au, Ag, Pt, or Ni with work function exceeding the work function of the most exterior semiconducting layer thus forming a Schottky barrier and reducing surface recombination of photo-generated charge carriers.

In one aspect, single junction photovoltaic devices may have an improved photo-response where simple homojunction described below possesses a back surface field created by highly doped (greater than 10¹⁷cm⁻³) back layer of the same charge polarity as the most interior layer and positioned between this layer and the back contact.

### Multiple Junction ZnO Photovoltaics:

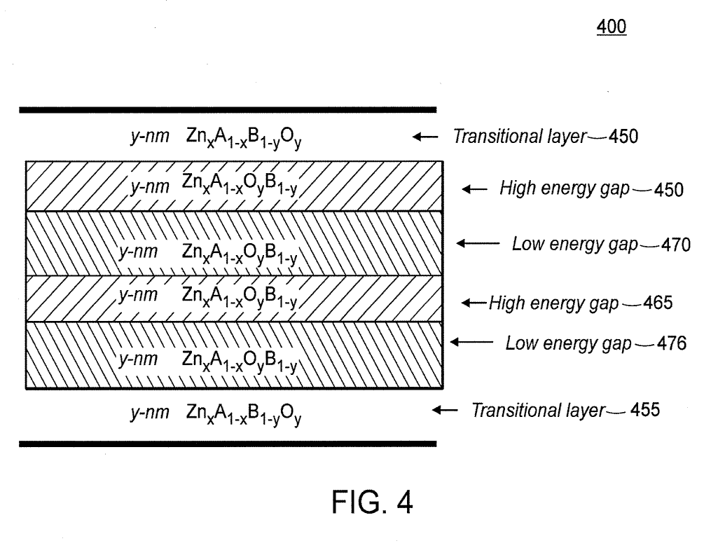

ZnO multi-junction photovoltaic devices designed to capture photons with energies ranging from ultraviolet to visible region of the energy spectrum can be realized through the sequential organometallic vapour phase epitaxy (OMVPE) deposition of different energy gap alloys of ZnO. Multiple ZnₓA₁₋ₓO_{y}B_{1-y} alloy materials may be selected and sequentially deposited in layers to form multiple junctions, each junction selected to capture a specified range of the electromagnetic spectrum. Photovoltaic devices designed with multiple junctions may thereby capture photons with a broad range of energies. Exemplary multi-junction ZnₓA₁₋ₓO_{y}B_{1-y} photovoltaic devices are shown in FIGS. 2A and 2B, where the p-ZnO and n-ZnO layers (260, 270) are one of the A- and/or B-alloyed ZnO compositions described herein, and form the first active region.

The device further includes a second set of active layers (265, 275) consisting of, e.g., a ZnₓMg₁₋ₓO or a ZnₓCd₁₋ₓO, or in the general case, a ZnₓA₁₋ₓO wherein A is selected from a group consisting of Ca, Sr, Be, or Ba. The second set of active layers comprises one layer 265 doped of same polarity as the substrate and a second layer 275 doped of opposite polarity. The device further includes a third set of active layers (263, 273) consisting of a ZnₓA₁₋ₓO_{y}B_{1-y} wherein A is selected in accordance with the selected material for the adjacent first heterostructure material; B is selected to be one of Te and Se in accordance with the selected material for adjacent layers (260, 270). The third set of active layers comprises one layer 263 doped to be of opposite polarity of the adjacent active layer 270 and a second layer 273 doped to be of the same polarity as the most exterior semiconducting layer.

The values for the x and y variables for each layer of ZnₓA₁₋ₓO_{y}B_{1-y} material may, in certain embodiments, be selected to form a gradient of materials. The gradient of materials reduces the lattice strain in the epitaxy layers and the electric field due to the first and second heterostructure reduces surface recombination of photo-generated charges at the surface. Each of the active layers may have a single alloyed composition, or the layers themselves may be made up of a graded composition. When graded, the active layers comprise regions of heterostructures to provide transitions in alloy composition to the adjacent layer. In one or more embodiments, the doped active layers are each selected to provide photon absorption at a selected subsection of the total spectral absorption range of the photovoltaic structure.

In other embodiments, multi-junction ZnₓA₁₋ₓO_{y}B_{1-y} photovoltaic devices may include transitional layers interposed between active layers, as shown in FIGS. 2C and 2D. FIGS. 2C and 2D illustrate embodiments in which the p-ZnO and n-ZnO layers (260, 270) are one of the A- and/or B-alloyed ZnO compositions described herein and are separated from the p-ZnO and n-ZnO substrates by transitional layers (215, 216). Transitional layers (215, 216) are comprise ZnₓA₁₋ₓO wherein A is selected from a group consisting of Ca, Sr, Be, or Ba and x is selected to form an intermediate composition and provide an interface between the n-type or p-type substrate (211, 212) and the adjacent second active layer material (265). The transitional layers (215, 216) may have a single composition, or may be made up of a graded composition and are selected to improve lattice matching between the substrate (211, 212) and the second active layer material (265). Typically, the transitional layers will be substantially thinner than the active layers of the photovoltaic structure. Whereas the active layers will be of approximately 5 μm in thickness (each active layer pair comprising the p-type and n-type portions, e.g. 260/270, 263/273, 265/275), the transitional layers (215, 216) will each be less than approximately 100 nm in thickness.

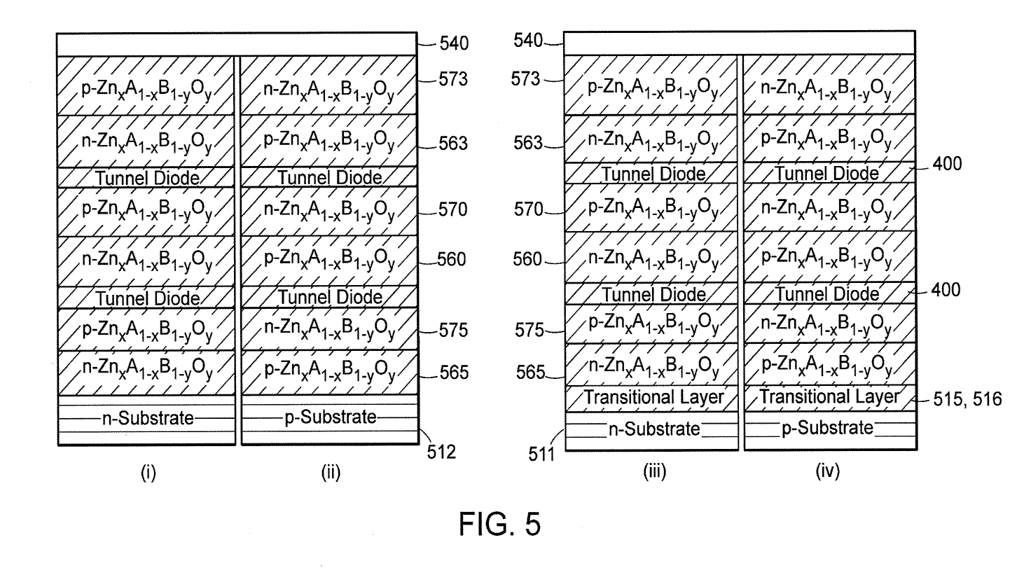

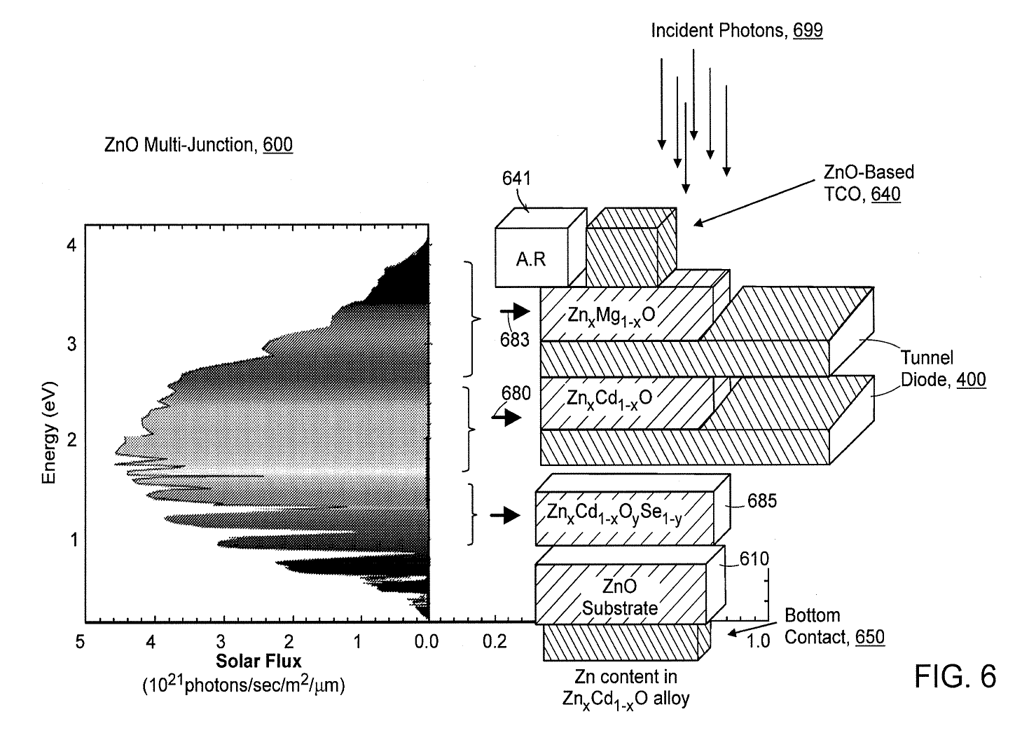

In other embodiments, ZnO multi-junction photovoltaic devices may be designed with ZnO resonant tunneling diodes interspaced between pairs of active layers to provide improved electron conductivity among the active layer pairs in the devices (lower resistivity between p-n junctions). For example, layers such as ZnₓMg₁₋ₓO, ZnO, ZnₓCd₁₋ₓO, ZnₓCd₁₋ₓO_{y}Se_{1-y} and ZnₓCd₁₋ₓO_{y}Te_{1-y} may be interspaced with ZnO tunneling diodes. Resonant tunnel diode structures as shown in FIGS. 3 and resonant tunneling interband diode structures (doped or undoped) as shown in FIG. 4 may be fabricated to facilitate an electron tunneling effect. Exemplary resonant tunnel diode structures are shown in FIGS. 3A and 3B. These diodes have a heavily doped p-n junction occupying a small physical distance. The heavy doping results in a broken bandgap, wherein conduction band electron states on the n-type layer are substantially aligned with valence band hole states on the p-type layer. The δ-doped planes provide degenerative doping that enables electron tunneling across the charge barrier. ZnO resonant tunnel diodes may be constructed to have an n-type doped ZnO layer (310), an adjacent undoped ZnO (320), an adjacent undoped layer of ZnₓA₁₋ₓO_{y}B_{1-y} with A- and B-selected to provide an alloy corresponding to the desired application, as described above (330), optionally an adjacent undoped ZnO layer (320) and an adjacent p-type doped ZnO layer (340). In certain embodiments, each doped and undoped layer with have a thickness of approximately y nm=115 nm.

A tunnel diode may also be achieved through bandgap shifting. An exemplary ZnₓA₁₋ₓO_{y}B_{1-y} resonant tunneling interband diode structure, which may be doped or undoped, is shown in FIG. 4. Interband tunnel diodes leverage bandgap misalignment to achieve the same electron tunneling effect that lowers resistivity between p-n junctions. Interband tunneling diode structure 400 comprises a first transitional layer 450, a first high energy gap layer 460, a first low energy gap layer 470, a second high energy gap layer 465, a second low energy gap layer 475 and a second transitional layer 455. By alternating energy gaps in this manner, electron tunneling is facilitated. The doping of the aforementioned layers, as well as the A-, B-, x, and y composition may be selected to correspond to and provide an interface between the first active layers (e.g., 560, 570) and the second active layers (e.g. 563, 573) and adjacent. Transitional layers 450 and 455 are provided to minimize lattice mismatch between the interband tunneling diode and surrounding materials.

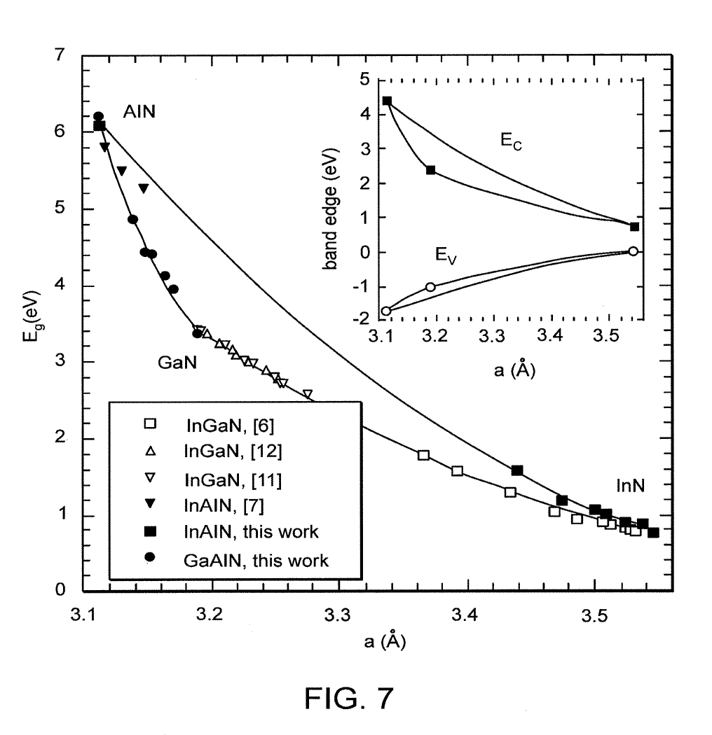

The use of resonant tunnel diodes between layers of a multi-junction photovoltaic device, as illustrated in FIG. 5, resolves discontinuities in the energy profile and lowers electron barriers between materials. FIG. 5 demonstrates the use of interband tunnel diodes (400), however degenerately doped tunnel diodes shown in FIG. 3.i and 3.ii could also be used, depending on the fabrication parameters of the particular application. Exemplary multi-junction ZnₓA₁₋ₓO_{y}B_{1-y}photovoltaic devices are shown in FIGS. 5A and 5B, where the p-ZnO and n-ZnO layers (260, 270) are one of the A- and/or B-alloyed ZnO compositions described herein. Interband resonant tunnel diodes (400) are disposed between the material layers that form each junction. The device includes a first set of heterostructures (563, 573) consisting of, e.g., a ZnₓMg₁₋ₓO or a ZnₓCd₁₋ₓO in the ideal case or a ZnₓA₁₋ₓO wherein A is selected from a group consisting of Ca, Sr, Be, or Ba; doped of same polarity as the most exterior semiconducting layer. The device includes a second set of heterostructures (565, 575) consisting of a ZnₓA₁₋ₓO_{y}B_{1-y} wherein A is selected in accordance with the selected material for the adjacent first heterostructure material; B is selected to be one of Te and Se in accordance with the selected material for adjacent layers (560, 570), and is doped to be of opposite polarity from the most exterior semiconducting layer. The values for the x and y variables for each layer are selected to form a gradient of materials. The interband resonant tunnel diodes (400) are provided to resolve discontinuities in the energy profiles and lower electron barriers between materials (563) and (570) and between materials (560) and (575). FIGS. 5C and 5D further include transitional layer (515, 516). The transitional layer (515, 516) may have a single composition, or may be made up of a graded composition and are selected to improve lattice matching between the doped substrate (511, 512) and the adjacent third active layer material (565).

According to certain embodiments, a multi-junction heterojunction design having resonant interband tunnel diodes, may be fabricated to function between ˜1.9 eV and ˜4.0 eV. Fabrication methods entail utilizing deposition and p-type doping processes described above by, for example, OMVPE at 400° C. and 800° C. for 7.5 mins each between 26 Torr and 100 Torr and n-type dopants selected from a group of Al, Ga, and In.

In one or more embodiments, such as those shown in FIG. 5, the photovoltaic cell includes a doped or undoped ZnₓA₁₋ₓO_{y}B_{1-y} heterostructure (540) disposed on the topmost active layer of a multi-junction photovoltaic device (573). The heterostructure provides an interface to the top surface layer of the structure that forms an energy barrier to electron transport. Specifically the heterostructure is a layer of material, similarly-doped and of similar chemical composition, but of different bandgap than the top surface layer (e.g. 573). The higher bandgap of the heterostructure (compared to the top surface layer) creates an energy barrier to surface recombination of electron and electron hole pairs. This construction improves the efficiency of the ZnₓA₁₋ₓO_{y}B_{1-y}-based photovoltaic devices by confining the drift of electrons to the surface. By way of example, FIG. 5.i may include active layer (573) comprising a ZnₓCd₁₋ₓO_{y} alloy with x=0.8 (and thus Cd composition of 20 atomic %) selected to capture the blue portion of the energy spectrum. Heterostructure layer (540) may be selected to have a composition with decreased concentration of Cd—for example a ZnₓCd₁₋ₓO_{y} alloy with x=0.95 (and thus Cd composition of 5 atomic %), thereby providing a higher bandgap than the topmost active layer.

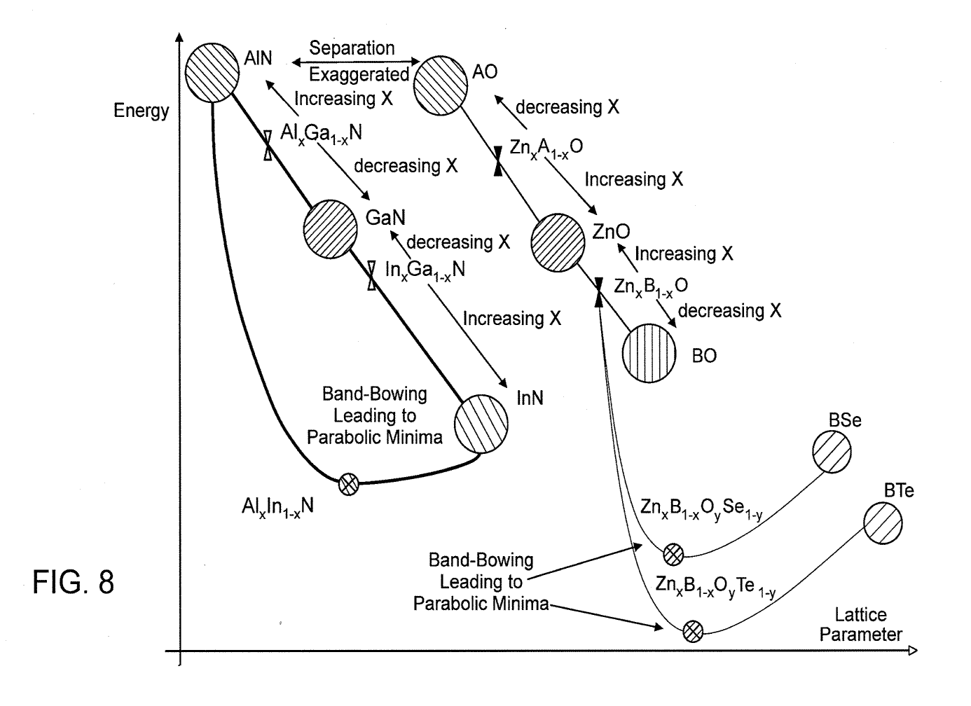

In one or more embodiments, such as those shown in FIG. 5, the photovoltaic cell further includes a heavily doped ZnₓA₁₋ₓO_{y}B_{1-y}-based back layer interposed between the innermost active layer (cell) and the substrate and/or back surface contact. For example, the heavily doped ZnₓA₁₋ₓO_{y}B_{1-y} region may include the doped transitional layer (515, 516) and may include a dopant concentration of approximately 1×10¹⁸ to 1×10²⁰ cm⁻³. The bottom-side contact between the stack of active layers and the substrate and/or back surface contact (e.g. 511, 512 and/or 650 or FIG. 6) prevents excessive recombination of electrons—electron hole pairs at that interface. The highly doped back layer material provides a highly conductive conduit to transmit excess carriers to external circuitry for the photovoltaic device. By transmitting excess carriers via the highly doped region to the external circuitry in this manner, the structure limits recombination inside the semiconductor material that would generate wasted light. Thus the construction improves efficiency of the photovoltaic device and helps to maximize energy delivered to external circuitry. Heavily doping ZnₓA₁₋ₓO_{y}B_{1-y} based back layers applies techniques know in the art, with respect to other materials (e.g. GaN, GaAs, InGaP, SiGe) to form a structure completely consisting of the present ZnO alloys. Alternately, a similarly conductive conduit for excess carrier transmission can be formed by highly doping the region of the substrate (511, 512) in closest proximity to the back surface contact. This alternate construction may also be used to improve the efficiency of the ZnₓA₁₋ₓO_{y}B_{1-y} based photovoltaic devices.

Multi-junction photovoltaic devices are not limited to structures comprising three active layers. The multi-junction photovoltaic device can be monolithic, i.e., prepared as a single structure having varying layers with varying compositions, properties and functions. A detailed description of an exemplary ZnO multi-junction photovoltaic device having a low to high bandgap stacking sequence, according to one or more embodiments, is provided below.

An n-type ZnₓCd₁₋ₓO is deposited on a n-type bulk ZnO substrate. The layer or substrate may consist of a highly doped (greater than 10¹⁷cm⁻³) region in order to provide a back surface field for devices in radiation prone environments. Or, the layer may be undoped and compositionally graded to the selected composition of the most interior junction thereby acting as a transitional layer wherein the composition is graded for values of x=1 at the substrate/epilayer interface to x=0.70 at the first epilayer.

Next a p-n junction may be formed, consisting of n-type Zn_{0.5}Cd_{0.5}O layer succeeded by p-type of Zn_{0.5}Cd_{0.5}O. Together, the layers facilitate absorption in the orange to near red region of the spectrum and have a carrier concentration exceeding 1×10¹⁵ cm⁻³, a and thickness between of each layer varied between approximately 0.2 μm and approximately 500 μm, with a preferred thickness of each layer between approximately 0.2 and 1.0 μm.

Next a tunnel diode may be fabricated from an alloy of ZnO, ZnₓCd₁₋ₓO, ZnₓMg₁₋ₓO where the values of x in the tunnel diode material allows a higher bandgap in the tunnel diode than in the preceding layer. The tunnel diode material may be selected such that loses due to adsorption are minimized and such that the doping levels exceed 1×10¹⁸ cm⁻³ to facilitate degenerative doping in either the n- or p-layer of the diode or in both.

Next, a p-n junction may be formed by depositing an n-type Zn_{0.7}Cd_{0.3}O succeeded by an p-type of Zn_{0.7}Cd_{0.3}O. Together, the layers facilitate absorption in the orange to near red region of the spectrum with a carrier concentration exceeding 1×10¹⁵ cm⁻³ and thickness of each layer varied between approximately 0.2 μm and approximately 500 μm with a preferred thickness of each layer between approximately 0.2 and 1.0 μm.

Next, a tunnel diode may be fabricated from an alloy of ZnO, ZnₓCd₁₋ₓO, ZnₓMg₁₋ₓO where the values of x in the tunnel diode material allows a higher bandgap in the tunnel diode than in the preceding layer. The tunnel diode material may be selected such that loses due to adsorption are minimized and such that the doping levels exceed 1×10¹⁸ cm⁻³ to facilitate degenerative doping in either the n- or p-layer of the diode or in both.

Next, a p-n junction may be formed by depositing an n-type Zn_{0.82}Cd_{0.18}O material succeeded by p-type Zn_{0.82}Cd_{0.80} material. Together the layers facilitate absorption in the yellow to green region of the spectrum, with a carrier concentration exceeding 1×10¹⁵ cm⁻³ and thickness between of each layer varied between approximately 0.2 μm and approximately 500 μm, with a preferred thickness of each layer between approximately 0.2 and 1.0 μm.

Next, a tunnel diode may be fabricated from an alloy of ZnO, ZnₓCd₁₋ₓO, ZnₓMg₁₋ₓO where the values of x in the tunnel diode material allows a higher bandgap in the tunnel diode than in the preceding layer. The tunnel diode may be constructed such that loses due to adsorption are minimized and such that the doping levels exceed 1×10¹⁸ cm⁻³ to facilitate degenerative doping in either the n- or p-layer of the diode or in both.

Next, a p-n junction may be formed by depositing an n-type Zn_{0.9}Cd_{0.1}O succeeded by p-type of Zn_{0.9}Cd_{0.1}O. Together, the layers facilitate absorption in the green to blue region of the spectrum, with a carrier concentration exceeding 1×10¹⁵ cm⁻³ and a thickness of each layer varied between approximately 0.2 μm and approximately 500 μm (with a preferred thickness of each layer between 0.2 and 1.0 μm).

Next, a tunnel diode may be fabricated from an alloy of ZnO, ZnₓCd₁₋ₓO ZnₓMg₁₋ₓO where the values of x in the tunnel diode material allows a higher bandgap in the tunnel diode than in the preceding layer. The tunnel diode may be formed such that loses due to adsorption are minimized and such that the doping levels exceed 1×10¹⁸ cm⁻³ to facilitate degenerative doping in either the n- or p-layer of the diode or in both.

Next, a p-n junction may be formed by depositing an n-type ZnO succeeded by p-type of ZnO. Together they facilitate absorption in the blue to violet region of the spectrum and have a carrier concentration exceeding 1×10¹⁵ cm⁻³ and thickness between of each layer varied between approximately 0.2 and approximately 500 μm (with a preferred thickness of each layer between approximately 0.2 and 1.0 μm).

Next, a tunnel diode preferably fabricated from ZnₓMg₁₋ₓO but similarly from ZnₓA₁₋ₓO where A is selected from Be, Ca, Sr, Ba may be formed, where the values of x in the tunnel diode material allows a higher bandgap in the tunnel diode than in the preceding layer. The tunnel diode may be constructed such that loses due to adsorption are minimized and such that the doping levels exceed 1×10¹⁸ cm⁻³ to facilitate degenerative doping in either the n- or p-layer of the diode or in both.

Next, a p-n junction may be formed by depositing an n-type Zn_{0.95}Mg_{0.05}O succeeded by p-type Zn_{0.95}Mg_{0.05}O. Together, they facilitate absorption in the violet to ultraviolet region of the spectrum and have a carrier concentration exceeding 1×10¹⁵ cm⁻³ and thickness between each layer varied between approximately 0.2 and approximately 500 μm (with a preferred thickness of each layer between 0.2 and 1.0 μm).

Next, a tunnel diode ideally fabricated from ZnₓMg₁₋ₓO but similarly from ZnₓA₁₋ₓO where A is selected from Be, Ca, Sr, Ba may be formed, where the values of x in the tunnel diode material allows a higher bandgap in the tunnel diode than in the preceding layer. The tunnel diode may be constructed such that loses due to adsorption are minimized and such that the doping levels exceed 1×10¹⁸ cm⁻³ to facilitate degenerative doping in either the n- or p-layer of the diode or in both.

Next, a p-n junction may be formed by depositing an n-type Zn_{0.85}Mg_{0.15}O succeeded by p-type of Zn_{0.85}Mg_{0.15}O. Together, the layers facilitate absorption in the violet to ultraviolet region of the spectrum and have a carrier concentration exceeding 1×10¹⁵ cm⁻³ and thickness between of each layer between approximately 0.2 μm and approximately 500 μm (with optimal thickness of each layer between 0.2 and 1.0 μm).

A final epilayer is then provided. The final epilayer consists of a heterostructure having a p-type ZnₓMg₁₋ₓO alloy. The values of x are selected such that the heterostructure material allows a higher bandgap than in the preceding p-layer and such that loses due to adsorption and surface recombination are minimized.

Next, a ZnO transparent contact layer is provided. The ZnO transparent contact layer is heavily doped with the polarity of the final layer thereby acting as an ohmic contact.

Finally, an antireflection dielectric stack is provided. The antireflection dielectric stack may comprise, for example, a titanium oxide/aluminum oxide stack with spectral reflectivity designed to minimize reflection is patterned and deposited after transparent contact layer.

FIG. 6 shows a plot of the electromagnetic spectrum of visible and ultraviolet light and indicates the typical amount of energy available from sunlight at a given eV (also known as solar flux). Juxtaposed to the plot is a schematic illustration of a multijunction photovoltaic device in which a general composition capable of providing a photoresponse at a specific spectral range. The general ZnO-alloy composition of the multiple junctions may be varied in order to target specific sub-spectral ranges. For example, multiple Zn₍₁₋ₓ₎Cd₍ₓ₎O junctions may be used, in which the composition of the cadmium in the alloy in each junction varies to generate materials having a band gap in the range from the blue to the green. Also included in the device of FIG. 6 are electrical contacts and tunneling diodes between adjacent photovoltaic junctions. The direction of incident photon irradiation may be selected such that the higher band gap materials are first exposed to photon irradiation. The photovoltaic devices may also be designed with suitable bandgaps to select either quantized portions of the spectral range or continuous segments of the spectral range.

The exemplary ZnO multi-junction structure with interband resonant tunnel diodes, shown in FIG. 6, is formed with a low to high bandgap stacking sequence. The structure is graphically illustrated alongside the full absorption range for the corresponding photovoltaic device. Specifically, the solar flux absorption (1×10¹² photon/sec/m²/μm) at various energy levels (eV) is graphically illustrated.

The structure 600 is formed with an n-type ZnO substrate 610. A first active layer material (685) of the composition ZnₓCd₁₋ₓO_{y}Se_{1-y} consists of an n-type and a p-type doped portion, is selected to provide absorption in the IR to red spectral range, and is deposited adjacent to the ZnO substrate. For example, the ZnₓCd₁₋ₓO_{y}Se_{1-y} of layer 685 may comprise Cd of approximately 30%, and Se of approximately 3-5%. A tunnel diode (400) is disposed adjacent to the first active layer material (685) to provide an interface (as described above) to an adjacent, second active layer material (680) of the composition ZnₓCd₁₋ₓO_{y}. The second active layer 680 comprises an n-type and p-type doped portion and is selected to provide absorption in the green region of the spectrum and is deposited adjacent to the resonant interface tunnel diode (400). For example, the ZnₓCd₁₋ₓO_{y} of layer 680 may comprise Cd of approximately 20%. Another tunnel diode (400) is disposed adjacent to the second active layer 680 and is arranged to provide an interface with the adjacent, third active layer material (683) of the composition ZnₓMg₁₋ₓO_{y}. The third active layer material (683) comprises an n-type and a p-type doped portion, and is deposited adjacent to the second resonant interface tunnel diode (400). Active layer 683 is selected to provide absorption in the blue and ultraviolet regions of the spectrum and, for example, may comprise approximately 10% Mg.

The structure further comprises an upper transparent ZnO contact electrode (640) and antireflective (A.R.) layer (641) which permits penetration by incident photons (699). In one or more embodiments, such as those shown in FIG. 6, the photovoltaic cell includes a transparent contact (640) based on ZnₓA₁₋ₓO_{y} transparent alloy, where A can be selected from In, Ga or Al on ZnₓA₁₋ₓO_{y}B_{1-y} devices. Fabricating the ZnO based transparent contact based on the ZnA₁₋ₓO transparent alloy includes the metallization of ZnO photovoltaic devices through self-contacting structures comprising undoped, and/or lightly doped and/or heavily doped ZnₓA₁₋ₓO_{y}B_{1-y} alloys. This construction overcomes the difficulty of finding a material having a sufficient work function to contact p-type layer (e.g. associated with ZnGaO, ZnInO).

### EXAMPLES OF PHOTOVOLTAIC DEVICE

### Example 1

### Formation of ZnO Based Alloy Material Having Band Gap Below 1.9 eV

ZnₓA₁₋ₓO_{y}B_{1-y} is deposited, wherein the composition of A and B as expressed by x and y respectively varies independently and/or dependently between 0 and 1 and A is selected from a group including Mg, Be, Ca, Sr, Cd, and In whereas B is selected from related elements including Te and Se and wherein the materials are lightly doped, and/or heavily doped, and/or undoped employing techniques described above on ZnO, III-nitride, III-phosphide, silicon, sapphire, or glass substrate leading to a homo- or hetero-junction device as shown in FIG. 1. Wherein alloying ZnO by ZnₓA₁₋ₓO_{y}B_{1-y} alloys where A is selected from a group including Mg, Be, Ca, Sr, Cd, and In whereas B is selected from a group of Te and Se allows for composition dependent (values of x and y) alterations to the lattice parameter of the binary oxide (ZnO) and consequently to the energy gap of the material wherein for instance selection of a quaternary defined by this invention for example of Zn_{0.7}Cd_{0.3}O_{0.98}Se_{0.02} or Zn_{0.3}Cd_{0.7}O_{0.98}Se_{0.02} or Zn_{0.3}Cd_{0.7}O_{0.98}Te_{0.02} allows for alteration of the bandgap below 1.9 eV.

### Example 2

### Formation of ZnO-based Single-Junction Having Band Gap in the Range of 6.0 to 1.4 eV

ZnₓA₁₋ₓO_{y}B_{1-y} is used to provide single junction photovoltaic device wherein the junction consists of a ZnₓA₁₋ₓO_{y}B_{1-y} absorbing between 6.0 and 1.4 eV wherein A is selected from a group consisting of Mg, Ca, Be, Sr, Ba, Mn, Cd, In and B is selected Te and/or Se and x and y is varied between 0 and 1 and is doped n-type and p-type to enable a p-n junction with n- and p-carrier concentration exceeding 10¹⁵ cm⁻² on ZnO, III-nitride, III-phosphide, silicon, sapphire, or glass substrate leading to a homo- or hetero-junction device as shown in FIG. 1A.

### Example 3

### Sequential Deposition for Providing Multi-Junction Photovoltaic Device

Sequential deposition of ZnₓA₁₋ₓO_{y}B_{1-y} is used to fabricate a multi-junction absorbing between 6.0 and 1.4 eV wherein A is selected from Mg, Ca, Be, Sr, Ba, Mn, Cd and In and B is selected from Te or Se and x and y is varied between 0 and 1 deposited in n-type or p-type sequence starting with a n- or p-type layer respectively thereby compensating favorably for intrinsic diffusion lengths and lifetimes of minority carriers and wherein the first group of cells consisting of a p-n junction of low energy gap is succeeded by a second group of cells consisting of a p-n junction of intermediate energy gap higher than the first group which is succeed by a third group of cell with energy gap higher than the second group and in which the three groups are doped n-type and p-type to enable a p-n junction with n- and p-carrier concentration exceeding 10¹⁵ cm⁻² on ZnO, III-nitride, III-phosphide, silicon, sapphire, or glass substrate leading to a hetero-junction device as shown in FIG. 2.

### Example 4

### Providing Multi-Junction Cell for Use with Interface

The sequential deposition of ZnₓA₁₋ₓO_{y}B_{1-y} is used to provide a multi-junction structure absorbing between 6.0 and 1.4 eV wherein A is selected from Mg, Ca, Be, Sr, Ba, Mn, Cd and In and B is selected from Te or Se and x and y is varied between 0 and 1 deposited in n-type or p-type sequence starting with a n- or p-type layer respectively thereby compensating favorably for intrinsic diffusion lengths and lifetimes of minority carriers and wherein the first group of cells consisting of a p-n junction of high energy gap is succeeded by a second group of cells consisting of a p-n junction of intermediate energy gap lower than the first group which is succeed by a third group of cell with energy gap lower than the second group and in which the three groups are doped n-type and p-type to enable a p-n junction with n- and p-carrier concentration exceeding 10¹⁵ cm⁻² on ZnO, III-nitride, III-phosphide, silicon, sapphire, or glass substrate leading to a hetero-junction device as shown in FIG. 2 which may subsequently be (1) utilized in its original form or (2) flip-bonded to a different surface with the first group of cells now becoming the outermost cells.

### Example 5

### Providing ZnO Alloy Transitional Layer

A transitional layer of type ZnₓA₁₋ₓO_{y}B_{1-y} is used wherein A is selected from a group of Mg, Be, Ba, Ca, Sr, Mn, Cd and In and B is selected Te or Se and x and y is varied between 0 and 1 with the compositional graded from the substrate to the first layer of the inner most cell as shown in FIG. 2.

### Example 6

### Providing ZnO Alloy Tunnel Diode with Degenerative Doping

ZnₓA₁₋ₓO_{y}B_{1-y} resonant tunnel diodes are fabricated wherein A is selected from Mg, Be, Ba, Ca, Sr, Cd, In and B is selected from Te and Se as to enable negative resistance and/or enhance current transition through the utility of bandgap offsets facilitated by doping levels exceeding 1×10¹⁸ cm⁻³ thereby constituting degenerative doping as shown in FIGS. 3(i) and 3(ii).

### Example 7

### Providing ZnO Alloy Interband Tunnel Diode

ZnₓA₁₋ₓO_{y}B_{1-y} resonant tunnel diodes are fabricated wherein A is selected from Mg, Be, Ba, Ca, Sr, Cd, In and B is selected from Te and Se and wherein energy gaps of ZnₓA₁₋ₓO_{y}B_{1-y} that are doped and/or undoped are varied to form heterostructures with sufficient band offset to enable current tunneling as shown in FIG. 5.

### Example 8

### Providing Multi-Junction Cells with Tunnel ZnO Alloy Tunnel Diode

The multi-junctions described above are the interspaced with ZnₓA₁₋ₓO_{y}B_{1-y} resonant tunnel diodes wherein A is selected from Mg, Be, Ba, Ca, Sr, Cd, In and B is selected from Te and Se as described in examples 6 and 7.

### Example 9

### Providing Multi-Junction Cells with Top-Layer Heterostructure

A ZnₓA₁₋ₓO_{y}B_{1-y} alloy is deposited on the topmost cell wherein the alloy is of higher energy gap than the topmost layer thereby forming a heterostructure and barrier to surface recombination of photo-generated electron hole pairs and in which the heterostructure may be doped with same polarity as the topmost cell or undoped.

### Example 10

### Providing Multi-Junction Cells with Heavily Doped Transitional Layer or Substrate

A heavily doped ZnₓA₁₋ₓO_{y}B_{1-y} alloy may also act as the transitional layer or a substrate containing an heavily doped region of the same polarity of the initial epilayer so as to create a back surface field and reduce the diffusion of minority carriers beyond the first p-n junction.

### Example 11

### Providing Multi-Junction Cells with Transparent Alloy Contact

Metallization of ZnO photovoltaic devices may be achieved through self contacting structures comprising of undoped, and/or lightly doped and/or heavily doped ZnO and ZnₓA₁₋ₓO alloys where A is selected from Cd, In, Al, Ga.

### OTHER EMBODIMENTS

The preceding discussion emphasizes the application of ZnₓA₁₋ₓO_{y}B_{1-y} alloy materials in photovoltaic devices. However, the ZnₓA₁₋ₓO_{y}B_{1-y} alloy materials and structures disclosed above are not restricted to use in photovoltaic devices. The materials may alternately be used in a variety of optical emitter devices in which optical emission in a broad range of the energy spectrum is desired (e.g. light emitting diodes (LEDs), laser diodes), in a variety of optical detector devices in which optical detection in a broad range of the energy spectrum is desired, and in a variety of other applications in which thin crystalline films of ZnₓA₁₋ₓO_{y}B_{1-y} alloy materials of the described compositions is desired. By alloying ZnO-based compounds with B-type alloy materials, the range of the energy spectrum that may be absorbed or emitted by ZnO-based structures is expanded to include effective absorption/emission of not only the green and blue range but also of the red range. The increased absorption/emission range permitted by the disclosed ZnₓA₁₋ₓO_{y}B_{1-y} alloy materials and the corresponding bandgap engineering techniques offer performance advantages that may be incorporated into any number of known technologies.

### Monolithic Devices Employing ZnₓB₁₋ₓO_{y}(Te,Se)_{1-y}

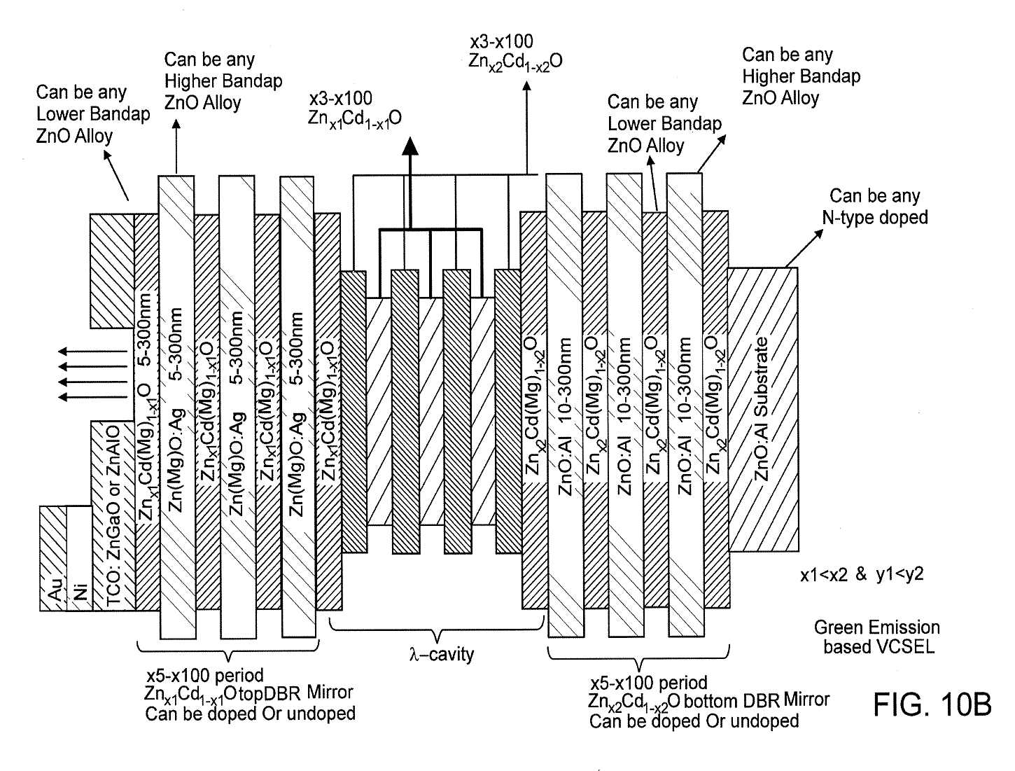

Monolithic optoelectronic and electronic devices which function discretely or in combination within the energy region of red to blue wavelengths are of significant interest to scientist and engineers. ZnO enables this functionality and the realization for instance of red, green and blue LEDs. FIG. 9 illustrates an example structure of a ZnO based red emitter diode. According to this example, the red based emitter diode comprises n-type and p-type regions (dopant concentration varying between approximately N_{d}˜10¹⁶ and N_{d}˜10¹⁹) with ZnO based alloys of composition ZnₓCd₁₋ₓO_{y}Se_{1-y} (alloying concentrations x and y are controllably varied), and emits light at wavelengths greater than approximately λ=650 nm.

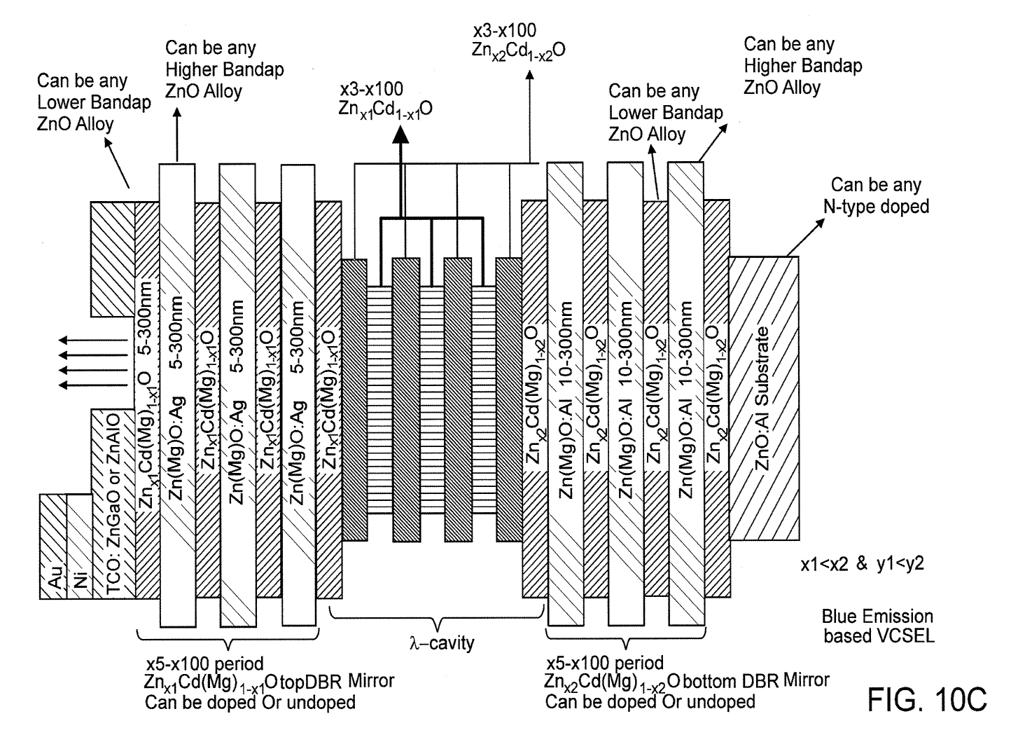

ZnO based compounds may also be employed in vertical cavity surface emitting laser devices, designed to emit light at discrete at portions of the spectrum (e.g. red, green and blue spectra). The vertical-cavity surface-emitting laser (VCSEL) is a type of semiconductor laser diode with laser beam emission perpendicular from the top surface (as opposed to edge-emitting semiconductor lasers which emit from surfaces formed by cleaving the individual chip out of a wafer). FIGS. 10 A, B and C illustrate three structures showing ZnO based red, green, and blue VCSELs, respectively. VCSELs may include (1) one or more layers of p-doped high bandgap zinc oxide alloys (e.g. ZnMgO:Ag) and one or more layers of undoped high bandgap alloys (e.g., ZnₓCd₁₋ₓO, ZnₓCd(Mg)₁₋ₓO); (2) one or more light emitting layers with bandgap tuned to a selected range of the spectrum (e.g., ZnₓCd₁₋ₓO_{y}Se_{1-y}, ZnₓCd₁₋ₓO); and (3) one or more layers of n-doped low bandgap zinc oxide alloys (e.g. ZnMgO:Al) and one or more layers of undoped high bandgap alloys (e.g., ZnₓCd₁₋ₓO, ZnₓCd(Mg)₁₋ₓO). The aforementioned layers may be interposed between a transparent zinc oxide based contact layer as describe above (comprising, for example, ZnGaO or ZnAlO) and an n-type substrate. The n-type substrate may comprise ZnO:Al as depicted in FIGS. 10A-C or any other suitable substrate material.

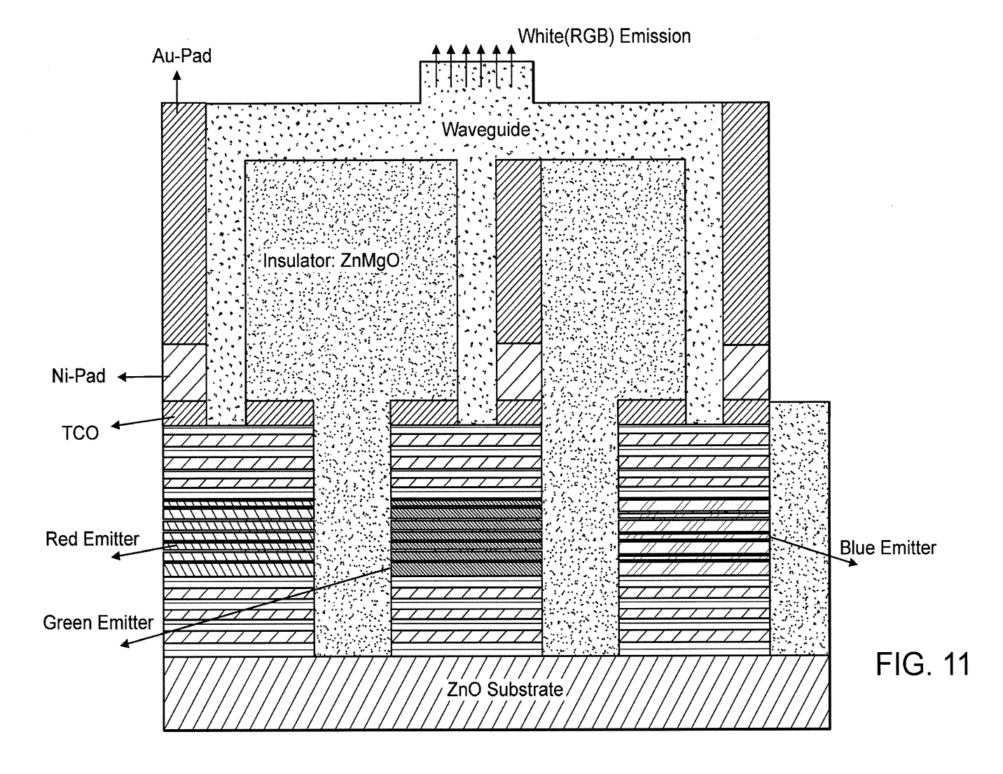

In another embodiment, a waveguide may be constructed to combine the discrete red, green and blue emissions from VCSEL devices, such as those described in FIGS. 10A-C above. FIG. 11 illustrates a monolithic device producing white RGB emission through the waveguided mixing of red, green and blue VCSEL emission. The wave guide consists of two materials of dissimilar indices of refraction or one of a very high index of refraction. While FIG. 11 illustrate the use of a ZnNgO insulator material between waveguide pathways, similar performance characteristics may be achieved by interposing any suitable insulator layer between waveguide pathways for each of the red, green and blue emissions.

It is to be understood that while the invention has been described in conjunction with the detailed description thereof, the foregoing description is intended to illustrate and not limit the scope of the invention, which is defined by the scope of the appended claims. Other aspects, advantages, and modifications are within the scope of the following claims.

### INCORPORATION BY REFERENCE

All abovementioned references, and particularly the following references, are herein incorporated in their entirety:

M. D. McCluskey, C. G. Van de Walle, C. P. Master, L. T. Romano, and N. M Johnson, Appl. Phys. Lett. 72 2725 (1998); B. -T. Liou, S. -H Yen, and Y. -K. Kuo, Appl. Phys. A: Materials Science and Processing, 81 651 (2005),

J. Wu, W. Walukewicz, K. M Yu, J. W. Ager III, S. X. Li, E. E. Haller, H. Lu, W. J. Schaff, “Universal Bandgap Bowing in Group III Nitride Alloys” Paper LBNL 51260, http://repositories.edlib.org/lbnl/LBNL-51260, and

K. S. Kim, A. Saxler, P. Kung, M. Razeghi and K. Y. Lim, Appl. Phys. Lett. 71, 800 (1997).

What is claimed is:

1. A ZnO composition comprising ZnₓA₁₋ₓB_{1-y}O_{y}, where x can vary from 0 to 1 and 0≦y≦1, A is selected from related elements including Mg, Be, Ca, Sr, Cd, and In and B is selected from a related elements including Te and Se.

2. The ZnO composition of claim 1, wherein 0.6≦x<1 and 0.7<y<1.

3. The ZnO composition of claim 2, wherein A, B, x and y are selected to provide a semiconductor having a bandgap of less than or equal to about 1.9 eV.

4. The ZnO composition of claim 3, wherein A comprises Cd and B comprises Te.

5. The ZnO composition of claim 1, wherein the composition is a p-type conductor material.

6. The ZnO composition of claim 5, wherein the composition is doped with a p dopant selected from the group consisting of Au, Ag and K.

7. The ZnO composition of claim 1, wherein the composition is an n-type conductor material.

8. The ZnO composition of claim 7, wherein the composition is doped with an n dopant selected from the group consisting of Al, Ga, In.

9. A ZnO crystalline film comprising ZnₓA₁₋ₓB_{1-y}O_{y} disposed on a substrate, where x can vary from 0 to 1 and 0<y<1, A is selected from related elements including Mg, Be, Ca, Sr, Cd, and In and B is selected from a related elements including Te and Se.

10. The ZnO crystalline film of claim 9, wherein 0.7<y<1.

11. The ZnO crystalline film of claim 9, wherein the layer is an epitaxy layer.

12. The ZnO crystalline film of claim 9, wherein the substrate is selected from the group consisting of ZnO, III-nitride, sapphire, silicon, ScAlMg, or glass substrates.

13. The ZnO crystalline film of claim 9, wherein each of x, y, A, and B is selected to provide a bandgap of less than about 1.9 eV.

14. The ZnO crystalline film of claim 9, wherein A comprises Cd and B comprises Te.

15. The ZnO crystalline film of claim 9, wherein the composition is a p-type conductor material.

16. The ZnO crystalline film of claim 15, wherein the composition is doped with a p dopant selected from the group consisting of Au, Ag and K.

17. The ZnO crystalline film of claim 9, wherein the composition is an n-type conductor material.

18. The ZnO crystalline film of claim 17, wherein the composition is doped with an n dopant selected from the group consisting of Al, Ga, In.

19. A semiconductor photovoltaic device having at least one junction comprising:
an n-type semiconductor material;
a p-type semiconductor material disposed in contact with the n-type semiconductor material;
wherein each of the n-type and p-type semiconductor materials comprises a compound of the form ZnₓA₁₋ₓO_{y}B_{1-y}, (0≦x≦1) (0≦y≦1), wherein A is selected from the group of related elements comprising Mg, Be, Ca, Sr, Ba, Mn, Cd, and In, wherein B is selected from the group of related elements comprising Te and Se, and wherein each of x, y, A, and B is selected to provide a junction bandgap corresponding to selected spectral range for absorption by the photovoltaic device.

20. The semiconductor photovoltaic device of claim 19, wherein the p-type semiconductor material comprises a semiconductor material doped with a dopant selected from the group of elements comprising: Ag, Au, and K.

21. The semiconductor photovoltaic device of claim 19, wherein the n-type semiconductor material comprises a semiconductor material doped with a dopant selected from the group of elements comprising: Al, In and As.

22. The semiconductor photovoltaic device of claim 19, wherein each of x, y, A, and B is selected to provide a junction bandgap of between approximately 6.0 eV and approximately 1.0 eV.

23. The semiconductor photovoltaic device of claim 19, further comprising a substrate of ZnO, the n-type doped semiconductor material disposed in contact with the substrate.

24. The semiconductor photovoltaic device of claim 19, wherein the n-type semiconductor material comprises a plurality of n-type materials of the form ZnₓA₁₋ₓO_{y}B_{1-y} and wherein x and y are varied incrementally from a first of the plurality of n-type materials to a last of the plurality of n-type materials to form a gradient of materials.

25. The semiconductor photovoltaic device of claim 19, wherein the p-type semiconductor material comprises a plurality of p-type materials of the form ZnₓA₁₋ₓO_{y}B_{1-y} and wherein x and y are varied incrementally from a first of the plurality of n-type materials to a last of the plurality of p-type materials to form a gradient of materials.

26. The semiconductor photovoltaic device of claim 11, wherein the gradient of the materials is selected to provide lattice matching among adjacent materials in the plurality of n-type materials.

27. The semiconductor photovoltaic device of claim 12, wherein the gradient of the materials is selected to provide lattice matching among adjacent materials in the plurality of p-type materials.

28. The semiconductor photovoltaic device of claim 13, wherein A and B are selected to provide a junction bandgap having efficient spectral response between approximately 2.0 eV and approximately 1.5 eV.

29. A semiconductor photovoltaic device comprising:
a plurality of semiconductor junctions, each comprising:
an n-type semiconductor material;
a p-type semiconductor material disposed in contact with the n-type semiconductor material;
wherein each of the n-type semiconductor material and the p-type semiconductor material comprises a compound of the form ZnₓA₁₋ₓO_{y}B_{1-y}, (0≦x≦1) (0≦y≦1), and wherein each of x, y, A, and B is selected to provide a bandgap for the semiconductor junction;
wherein the plurality of semiconductor junctions are selected to correspond to a selected spectral range for the semiconductor photovoltaic device.

30. The semiconductor photovoltaic device of claim 29, wherein A is selected from the group of related elements consisting of Mg, Be, Ca, Sr, Ba, Mn, Cd, and In, and wherein B is selected from the group of related elements consisting of Te and Se.

31. The semiconductor photovoltaic device of claim 29, wherein the plurality of semiconductor junctions is disposed on a substrate

32. The semiconductor photovoltaic device of claim 29, wherein a first of the plurality of semiconductor junctions comprises n-type and p-type semiconductor materials to provide a first bandgap and a second of the plurality of semiconductor junctions comprises n-type and p-type semiconductor materials to provide a second bandgap, the first bandgap being higher than the second bandgap.

33. The semiconductor photovoltaic device of claim 32 wherein the first semiconductor junction is disposed on the substrate and the second semiconductor junction is disposed on the first semiconductor junction.

34. The semiconductor photovoltaic device of claim 33 wherein the second semiconductor junction is disposed on the substrate and the first semiconductor junction is disposed on the second semiconductor junction.

35. The semiconductor photovoltaic device of claim 32, further comprising a resonant interband tunnel diode disposed between and in electrical communication with the first semiconductor junction and the second semiconductor junction.

36. The semiconductor photovoltaic device of claim 29, wherein each of x, y, A, and B is selected to provide a junction bandgap of between approximately 6.0 eV and approximately 1.0 eV.

37. The semiconductor photovoltaic device of claim 32, wherein for the first of the semiconductor junctions, each of x, y, A, and B is selected to provide a junction bandgap of between approximately 3.0 eV and approximately 4.0 eV and wherein for the second of the semiconductor junctions, each of x, y, A, and B is selected to provide a junction bandgap of between approximately 1.0 eV and approximately 3.0 eV.

38. The semiconductor photovoltaic device of claim 29, wherein the junctions range from higher bandgap to lower bandgap ZnₓA₁₋ₓO_{y}B_{1-y} films.

39. The semiconductor photovoltaic device of claim 38, wherein the topmost ZnₓA₁₋ₓO_{y}B_{1-y} film is the higher bandgap material.

40. The semiconductor photovoltaic device of claim 38, wherein the topmost ZnₓA₁₋ₓO_{y}B_{1-y} film is the lower bandgap material.

41. The semiconductor photovoltaic device of claim 35, wherein the ZnO tunnel diodes comprise delta doped regions of n and p type carriers deposited between 100° C. and 900° C.

42. The semiconductor photovoltaic device of claim 35, wherein the ZnO resonant interband tunnel diodes comprising compounds of ZnₓA₁₋ₓO_{y}B_{1-y} where x and y can vary from 0 to 1, A is selected from related elements including Mg, Be, Ca, Sr, Cd, and In and B is selected from a related elements including Te and Se.

43. The semiconductor photovoltaic device of claim 16, further comprising electrical contacts for connecting to an outside circuit, said contacts selected from the group consisting of silver, gold, nickel, and platinum, intermetallics, amalgams and/or eutectics of silver, gold, platinum, and nickel, oxides of silver, and nickel, and transparent conducting oxides including indium tin oxide, zinc indium oxide, zinc tin oxide or conducting n-ZnO doped with aluminum, and/or indium, and/or gallium.

44. A method of making a photodiode comprising:
epitaxially growing a first p/n junction on a crystalline substrate in a CVD process in a continuous process, the first p/n junction comprising:
n-type semiconductor material;
a p-type semiconductor material, wherein each of the first doped semiconductor material and the second doped semiconductor material comprises a compound of the form ZnₓA₁₋ₓO_{y}B_{1-y} (0≦x≦1) (0≦y≦1), and wherein each of x, y, A, and B is selected to provide a bandgap for the semiconductor junction,
by varying the composition of a vapor source of zinc, a vapor source of A, a vapor source of O and a vapor source of B.

45. The method of claim 44, further comprising:
epitaxially growing a second p/n junction in a CVD process in a continuous system, the first p/n junction comprising:
a second n-type semiconductor material;
a second a p-type semiconductor material, wherein each of the first doped semiconductor material and the second doped semiconductor material comprises a compound of the form ZnₓA₁₋ₓO_{y}B_{1-y} (0≦x≦1) (0≦y≦1), and wherein each of x, y, A, and B is selected to provide a bandgap for the semiconductor junction,
by varying the composition of a vapor source of zinc, a vapor source of A, a vapor source of O and a vapor source of B.

46. The method of claim 44, further comprising:
epitaxially growing a third p/n junction in a CVD process in a continuous system, the second p/n junction comprising:
a third n-type semiconductor material;
a third a p-type semiconductor material, wherein each of the first doped semiconductor material and the second doped semiconductor material comprises a compound of the form ZnₓA₁₋ₓO_{y}B_{1-y}, (0≦x≦1) (0≦y≦1), and wherein each of x, y, A, and B is selected to provide a bandgap for the semiconductor junction,
by varying the composition of a vapor source of zinc, a vapor source of A, a vapor source of O and a vapor source of B.

47. The method of claim 45, further comprising:
epitaxially growing a a resonant interband tunnel diode after the epixtaixal growth of the first p/n junction and before the growth of the second p/n junction.

48. The method of claim 45, further comprising:
epitaxially growing a transparent electrical contact on the uppermost surface of the photodiode, the contact comprising a conducting oxides selected from the group consisting of indium tin oxide, zinc indium oxide, zinc tin oxide or conducting n-ZnO doped with aluminum, and/or indium, and/or gallium,
by varying the composition of a vapor source of zinc, a vapor source of Al, and/or In and/or Ga, and a vapor source of O.

49. A device, comprising:
at least one n-type semiconductor material;
at least one p-type semiconductor material disposed in contact with the n-type semiconductor material to form a semiconductor junction;
wherein each of the n-type semiconductor material and the p-type semiconductor material comprises a compound of the form ZnₓA₁₋ₓO_{y}B_{1-y}, (0≦x≦1) (0≦y≦1), and wherein each of x, y, A, and B is selected to provide a bandgap for the semiconductor junction.

50. The device of claim 49, wherein the device is selected from the group consisting of photodiodes, solar cells, optical detectors, optical emitters, light emitting diodes (LEDs), and laser diodes.

51. An optoelectronic device, comprising:
at least one n-doped semiconductor material;
at least one p-doped semiconductor material;
at least one semiconductor material disposed in contact with each of the n-doped semiconductor material and the p-doped semiconductor material;
wherein each of the n-doped semiconductor material, the p-doped semiconductor material, and the semiconductor material comprises a compound of the form ZnₓA₁₋ₓO_{y}B_{1-y}, (0≦x≦1) (0≦y≦1), A is selected from related elements including Mg, Be, Ca, Sr, Cd, and In and B is selected from a related elements including Te and Se, and wherein each of A, B, x and y is selected to provide a bandgap for the semiconductor material.

52. The optoelectronic device of claim 51, wherein the device is selected from the group consisting of photodiodes, optical emitters, light emitting diodes (LEDs), and laser diodes.

53. The optoelectronic device of claim 52, wherein the device comprises a LED and wherein each of A, B, x and y is selected to provide a bandgap of the semiconductor material less than approximately 1.9 eV.

54. The optoelectronic device of claim 53, wherein the LED emits light at a wavelength of greater than approximately 650 nm.

55. The optoelectronic device of claim 53, wherein A comprises Cd, B comprises Se, 0.7≦x≦1, and 0.9≦y≦1.

56. The optoelectronic device of claim 52, wherein the optical emitter comprises a vertical-cavity surface-emitting laser (VCSEL).

57. An optoelectronic device comprising a plurality of optical emitters, each optical emitter including:
at least one n-doped semiconductor material;
at least one p-doped semiconductor material;
at least one semiconductor material disposed in contact with each of the n-doped semiconductor material and the p-doped semiconductor material;
wherein each of the n-doped semiconductor material, the n-doped semiconductor material, and the semiconductor material comprises a compound of the form ZnₓA₁₋ₓO_{y}B_{1-y}, (0≦x≦1) (0≦y≦1), A is selected from related elements including Mg, Be, Ca, Sr, Cd, and In and B is selected from a related elements including Te and Se, wherein each of A, B, x and y is selected to provide a bandgap for the semiconductor material; and
wherein the bandgap for the semiconductor material of each optical emitter is selected to emit electromagnetic radiation at a discrete portion of the energy spectrum.

58. The optoelectronic device of claim 57, further comprising a waveguide for guiding electromagnetic radiation emitted by each of the plurality of optical emitters, the optoelectronic device emitting white RGB electromagnetic radiation.

59. An optoelectronic device, configured and arranged to emit light at one or more wavelengths, comprising a ZnO-based material of the composition ZnₓA₁₋ₓB_{1-y}O_{y}, where x can vary from 0 to 1 and 0≦y≦1, A is selected from related elements including Mg, Be, Ca, Sr, Cd, and In and B is selected from a related elements including Te and Se.

60. A light emitting diode (LED) comprising a ZnO-based material of the composition ZnₓA₁₋ₓB_{1-y}O_{y}, where x can vary from 0 to 1 and 0≦y≦1, A is selected from related elements including Mg, Be, Ca, Sr, Cd, and In and B is selected from a related elements including Te and Se.

61. A photodiode comprising a ZnO-based material of the composition ZnₓA₁₋ₓB_{1-y}O_{y}, where x can vary from 0 to 1 and 0≦y≦1, A is selected from related elements including Mg, Be, Ca, Sr, Cd, and In and B is selected from a related elements including Te and Se.

62. An optical detector comprising a ZnO-based material of the composition ZnₓA₁₋ₓB_{1-y}O_{y}, where x can vary from 0 to 1 and 0≦y≦1, A is selected from related elements including Mg, Be, Ca, Sr, Cd, and In and B is selected from a related elements including Te and Se.

63. A laser diode comprising a ZnO-based material of the composition ZnₓA₁₋ₓB_{1-y}O_{y}, where x can vary from 0 to 1 and 0≦y≦1, A is selected from related elements including Mg, Be, Ca, Sr, Cd, and In and B is selected from a related elements including Te and Se.
